(19) United States
(12) Patent Application Publication
(10) Pub. No.: US 2014/0231772 A1
(43) Pub. Date: Aug. 21, 2014

(54) MATERIAL FOR ORGANIC ELECTROLUMINESCENT ELEMENTS, AND ORGANIC ELECTROLUMINESCENT ELEMENT USING THE SAME

(71) Applicant: Idemitsu Kosan Co., Ltd., (unknown)

(72) Inventors: Takushi Shiomi, Sodegaura-shi (JP); Ryohei Hashimoto, Sodegaura-shi (JP); Hideaki Nagashima, Sodegaura-shi (JP)

(73) Assignee: Idemitsu Kosan Co., Ltd.

(21) Appl. No.: 14/234,890

(22) PCT Filed: Nov. 2, 2012
(86) PCT No.: PCT/JP2012/007051

§ 371 Date: Jan. 24, 2014

(30) Foreign Application Priority Data
Nov. 7, 2011 (JP) 2011-243458

(51) Int. Cl. H01L 51/00

(52) U.S. Cl. CPC H01L 51/0067; H01L 51/0072; H01L 51/0073
USPC 257/40; 548/440; 546/276.7

(57) ABSTRACT

A compound represented by the following formula (1):

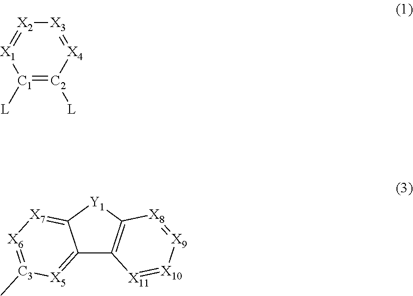

wherein C₁ and C₂ are independently a carbon atom; X₁ to X₄ are independently N, CH or C(R₁); L is a group represented by the formula (2): -L₁-(A)ₙ; L₁ is a group represented by the formula (3); A is alkyl, cycloalkyl, alkoxy, cycloalkoxy, aryl, aryloxy, arylthio, heteroaryl, heteroaryloxy, amino, silyl, diaryloxyphosphinyl, a divalent group corresponding to these groups, fluoro or cyano.

### TECHNICAL FIELD

The invention relates to a material for an organic electroluminescence device and an organic electroluminescence device.

### BACKGROUND ART

An organic electroluminescence (EL) device includes a fluorescent organic EL device or a phosphorescent organic EL device, and a device design optimum for the emission mechanism of each type of organic EL device has been studied. It is known that a highly efficient phosphorescent organic EL device cannot be obtained by merely applying fluorescent device technology due to the emission characteristics. The reasons therefor are generally considered to be as follows.

Specifically, since phosphorescence utilizes triplet excitons, a compound used for forming an emitting layer must have a large energy gap. This is because the energy gap (hereinafter often referred to as “singlet energy”) of a compound is normally larger than the triplet energy (in the invention, the difference in energy between the lowest excited triplet state and the ground state) of the compound.

In order to confine the triplet energy of a phosphorescent dopant material efficiently in an emitting layer, it is required to use, in an emitting layer, a host material having a triplet energy larger than that of the phosphorescent dopant material. Further, an electron-transporting layer and a hole-transporting layer are required to be provided adjacent to the emitting layer, and a compound having a triplet energy larger than that of a phosphorescent dopant material is required to be used in an electron-transporting layer and a hole-transporting layer.

As mentioned above, if based on the conventional design concept of an organic EL device, it leads to the use of a compound having a larger energy gap as compared with a compound used in a fluorescent organic EL device in a phosphorescent organic EL device. As a result, the driving voltage of the entire organic EL device is increased.

Further, in a hydrocarbon-based compound having a high resistance to oxidation or reduction, which has been useful in a fluorescent device, the π electron cloud spreads largely, and hence it has a small energy gap. Therefore, in a phosphorescent organic EL device, such a hydrocarbon-based compound is hardly selected. As a result, an organic compound including a hetero atom such as oxygen and nitrogen is selected, and hence a phosphorescent organic EL device has a problem that it has a short lifetime as compared with a fluorescent organic EL device.

In addition, a significantly long exciton relaxation speed of a triplet exciton of a phosphorescent dopant material as compared with that of a singlet exciton greatly effects the device performance. That is, emission from the singlet exciton has a high relaxation speed that leads to emission, and hence, diffusion of excitons to peripheral layers (such as a hole-transporting layer and an electron-transporting layer) of an emitting layer hardly occurs, whereby efficient emission is expected. On the other hand, in the case of emission from the triplet exciton, since it is spin-forbidden and has a slow relaxation speed, diffusion of excitons to peripheral layers tends to occur easily, and as a result, thermal energy deactivation occurs from other compounds than a specific phosphorescent emitting compound. That is, in a phosphorescent organic EL device, control of a recombination region of electrons and holes is more important than that of a fluorescent organic EL device.

For the reasons mentioned above, in order to improve the performance of a phosphorescent organic EL device, material selection and device design that are different from a fluorescent organic EL device have come to be required.

If a structure, in which the π conjugation is cut, is taken in order to increase the triplet energy of the compound, transporting properties of carriers may be deteriorated. That is, in order to improve the transporting properties of carriers, it is required to elongate the u conjugation. However, if the π conjugation is elongated, a problem then arises that the triplet energy is lowered.

Patent Document 1 discloses a compound in which one bonds to the 9^{th} position of carbazole and the other bonds to other positions than the 9^{th} position with a linker being disposed therebetween. In this invention, as the linker, metaphenylene, orthophenylene, dibenzofuran or the like are selected.

Of these, it has been revealed that an organic EL device using a compound having an orthophenylene linker shown below is excellent in external quantum efficiency and lifetime.

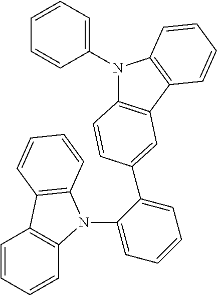 [SMILES: c1ccc(-n2c3ccccc3c3cc(-c4ccccc4-n4c5ccccc5c5ccccc54)ccc32)cc1]

Patent Document 2 discloses a symmetrical compound in which N-phenylcarbazole is bonded to terminals with a linker being disposed therebetween. This linker, as in the case of a compound shown below, is bonded to the ortho position of the phenyl group of N-phenylcarbazole.

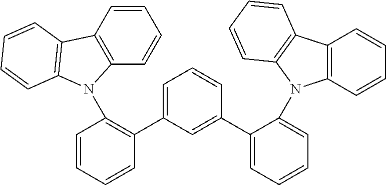 [SMILES: c1cc(-c2ccccc2-n2c3ccccc3c3ccccc32)cc(-c2ccccc2-n2c3ccccc3c3ccccc32)c1]

### RELATED ART DOCUMENTS

### Patent Documents

Patent Document 1: WO2008/156105
Patent Document 2: WO2009/119163

An object of the invention is to provide a material having a high triplet energy which can be used as a host material for blue phosphorescent emission.

In order to attain the above-mentioned object, the inventors made extensive studies. As a result, they have found that, in the case of a phenylene linker, by taking the ortho position, the planarity of a compound can be improved, and that by providing a compound having a good carrier balance within an emitting layer by improving the carrier transporting properties while maintaining the triplet energy, the performance of an organic EL device can be improved. The invention has been made based on this finding.

According to the invention, the following compound, the material for an organic electroluminescence device and the organic electroluminescence device are provided.

1. A compound represented by the following formula (1):

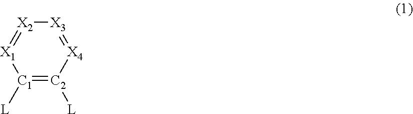

wherein in the formula (1), C₁ and C₂ are independently a carbon atom;

X₁ to X₄ are independently N, CH or C(R₁);

R₁ are independently a single bond, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 6 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphonyl group, a fluoro group or a cyano group; provided that if two adjacent groups of X₁ to X₄ are both C(R₁) and one of R₁s is a single bond, the single bond is used in the bond to the other R₁ to form a ring comprising the two carbon atoms;

L is independently a group represented by the following formula (2):

-L₁-(A)ₙ (2)

wherein in the formula (2), n is the number of A being bonded sequentially, and is an integer of 0 to 6; when n is 2 or more, plural As may be the same or different;

A is a group selected from a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 6 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a divalent group corresponding thereto, a fluoro group and a cyano group;

L₁ is a group represented by the following formula (3):

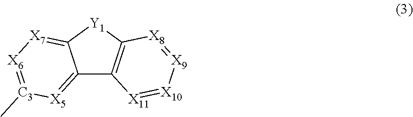

wherein in the formula (3), C₃ is a carbon atom, and C₃ is bonded to C₁ or C₂ in the formula (1);

Y₁ is O, S, NH, N(R₂) or a nitrogen atom that is bonded to A;

X₅ to X₁₁ are independently N, CH, C(R₃) or a carbon atom that is bonded to A;

R₂ and R₃ are independently a single bond, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 6 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group, provided that if two adjacent groups of X₆ to X₁₁ are both C(R₃) and one of R₃s is a single bond, the single bond is used in the bond to the other R₃ to form a ring comprising the two carbon atoms.

2. The compound according to 1, wherein A in at least one of the two Ls comprises a substituted or unsubstituted heteroaryl group including 13 to 18 ring atoms or a substituted or unsubstituted heteroarylene group including 13 to 18 ring atoms.
3. The compound according to 1 or 2, wherein A in at least one of the two Ls comprises a heteroaryl group or a heteroarylene group represented by the following formula (4):

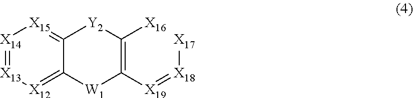

wherein in the formula (4), X₁₂ to X₁₉ are independently N, CH, C(R₄) or a carbon atom that is bonded to L₁ or A;

R₄ is independently a single bond, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group, provided that if two adjacent groups of X₁₂ to X₁₉ are both C(R₄) and one of R₄s is a single bond, the single bond is used in the bond to the other R₄ to form a ring comprising the two carbon atoms;

Y₂ is O, S, NH, N(R₅) or a nitrogen atom that is bonded to L₁ or A;

R₅ is a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group;

W₁ is a single bond, O, S, S(═O)₂, P(R₆), P(═O)(R₇), N(R₈), Si(R₉(R₁₀), C(R₁₁)(R₁₂), a nitrogen atom that is bonded to L₁ or A or a carbon atom that is bonded to L₁ or A; and

R₆ to R₁₂ are independently a hydrogen atom, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group.

4. The compound according to any of 1 to 3, wherein A in at least one of the two Ls comprises a heteroaryl group or a heteroarylene group represented by the following formula (5):

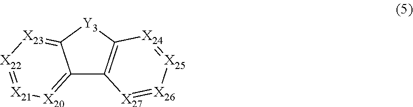

wherein in the formula (5), X₂₀ to X₂₇ are independently N, CH, C(R₁₃) or a carbon atom that is bonded to L₁ or A;

R₁₃ is independently a single bond, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group, provided that if two adjacent groups of X₂₀ to X₂₇ are both C(R₁₃) and one of R₁₃s is a single bond, the single bond is used in the bond to the other R₁₃ to form a ring comprising the two carbon atoms;

Y₃ is O, S, NH, N(R₁₄) or a nitrogen atom that is bonded to L₁ or A;

R₁₄ is a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group:

5. The compound according to any of 1 to 4, wherein n in one of the two Ls is 0.
6. A material for an organic electroluminescence device comprising the compound according to any of 1 to 5.
7. An organic electroluminescence device comprising:

a cathode and an anode;

one or more organic thin film layers including an emitting layer between the cathode and the anode; and

at least one layer of the organic thin film layers comprising the material for an organic electroluminescence device according to 6.

8. The organic electroluminescence device according to 7, wherein the emitting layer comprises the material for an organic electroluminescence device as a host material.
9. The organic electroluminescence device according to 7 or 8, wherein the emitting layer comprises a phosphorescent emitting material which is an ortho-metalated complex of a metal atom selected from iridium (Ir), osmium (Os) and platinum (Pt).
10. The organic electroluminescence device according to any of 7 to 9, wherein the layer that comprises the material for an organic electroluminescence device forms an electron-transporting region between the cathode and the emitting layer.
11. The organic electroluminescence device according to any of 7 to 10, wherein the layer that comprises the material for an organic electroluminescence device is an electron-injecting layer between the emitting layer and the cathode.
12. The organic electroluminescence device according to any of 7 to 9, wherein the layer that comprises the material for an organic electroluminescence device is a hole-transporting region between the emitting layer and the anode.

According to the invention, a compound having a high triplet energy (T1) and excellent carrier-transporting properties and a material for an organic EL device containing the same can be provided.

### BRIEF DESCRIPTION OF THE DRAWINGS

FIG. 1 is a schematic view showing the layer structure of the organic EL device according to one embodiment of the invention; and

FIG. 2 is a schematic view showing the layer structure of the organic EL device according to another embodiment of the invention.

### MODE FOR CARRYING OUT THE INVENTION

Conventional materials for an organic electroluminescence device have a problem that carrier transporting properties are lowered if the conjugation is cut in order to improve the triplet energy (T1), and the triplet energy (T1) is lowered if the conjugation is elongated in order to improve carrier transporting properties.

In the material of the invention, a group including a dibenzofuranyl group, a carbazolyl group or a dibenzothiophenyl group can be linked with an orthoarylene linker, whereby the triplet energy (T1) of the compound can be maintained at a high level. By linking the 2^{nd} position of the dibenzofuranyl group, the 3^{rd} position of the carbazolyl group and the 2^{nd} position of the dibenzofuranyl group with an orthoarylene linker, a material which has excellent stability can be obtained.

By linking a group including a dibenzofuranyl group, a carbazolyl group or a dibenzothiophenyl group with an orthoarylene linker, the linked groups can be always arranged in parallel, and as a result, the number of cubic structures that can be taken by the material molecules is reduced. This means that the vibration level that can be taken by material molecules is reduced, whereby more exitons are confined within the emitting material in the device. That is, by using the material of the invention, the triplet energy (T1) of the compound can be kept at a high level.

By linking a group including a dibenzofuranyl group, a carbazolyl group or a dibenzothiophenyl group with an orthoarylene linker, the linked groups are always arranged in parallel, whereby the planarity of the material molecules is improved. As a result, the orientation of the material molecules in the device is improved, and as a result, the carrier transporting properties are improved and the carriers will be well-balanced.

The compound of the invention is represented by the following formula (1):

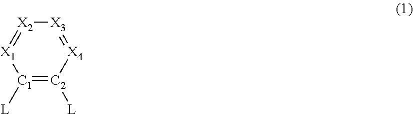

wherein in the formula (1), C₁ and C₂ are independently a carbon atom;

X₁ to X₄ are independently N, CH or C(R₁);

R₁ are independently a single bond, a substituted or unsubstituted alkyl group including 1 to 20 carbon atoms, a substituted or unsubstituted cycloalkyl group including 3 to 18 carbon atoms that form a ring (hereinafter referred to as “ring carbon atoms”), a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 6 to 18 ring carbon atoms, a substituted or unsubstituted heteroaryl group including 5 to 18 atoms that form a ring (hereinafter referred to as “ring atoms”), a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group; provided that if two adjacent groups of X₁ to X₄ are both C(R₁) and one of R₁s is a single bond, the single bond is used in the bond to the other R to form a ring comprising the two carbon atoms.

L is independently a group represented by the following formula (2):

-L₁-(A)ₙ (2)

wherein in the formula (2), n is the number of A being bonded sequentially, and is an integer of 0 to 6; when n is 2 or more, plural As may be the same or different.

When n is 2 or more, it means that plural As are bonded sequentially, and it does not mean that L₁ is substituted by plural As. For example, when n is 2, the group represented by the above formula (2) is -L₁-A-A. A is a monovalent or divalent group.

A is a group selected from a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 6 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a divalent group corresponding thereto, a fluoro group and a cyano group.

L₁ is a group represented by the following formula (3):

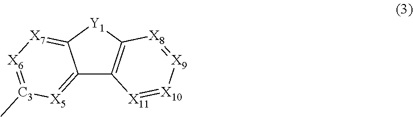

wherein in the formula (3), C₃ is a carbon atom, and C₃ is bonded to C₁ or C₂ in the formula (1);

Y₁ is O, S, NH, N(R₂) or a nitrogen atom that is bonded to A;

X₅ to X₁₁ are independently N, CH, C(R₃) or a carbon atom that is bonded to A.

R₂ and R₃ are independently a single bond, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 6 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group, provided that if two adjacent groups of X₆ to X₁₁ are both C(R₃) and one of R₃s is a single bond, the single bond is used in the bond to the other R₃ to form a ring comprising the two carbon atoms.

It is preferred that A in at least one of the two Ls be a substituted or unsubstituted heteroaryl group including 13 to 18 ring atoms or a substituted or unsubstituted heteroarylene group including 13 to 18 ring atoms.

It is preferred that A in at least one of the two Ls comprise a heteroaryl group or a heteroarylene group represented by the following formula (4):

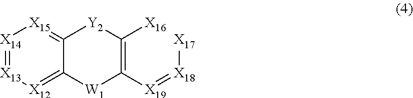

In the formula (4), X₁₂ to X₁₉ are independently N, CH, C(R₄) or a carbon atom that is bonded to L₁ or A;

R₄ is independently a single bond, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group, provided that if two adjacent groups of X₁₂ to X₁₉ are both C(R₄) and one of R₄s is a single bond, the single bond is used in the bond to the other R₄ to form a ring comprising the two carbon atoms.

Y₂ is O, S, NH, N(R₅) or a nitrogen atom that is bonded to L₁ or A;

R₅ is a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group.

W₁ is a single bond, O, S, S(═O)₂ P(R₆), P(═O)(R₇), N(R₈), Si(R₉)(R₁₀), C(R₁₁)(R₁₂), a nitrogen atom that is bonded to L₁ or A or a carbon atom that is bonded to L₁ or A.

R₆ to R₁₂ are independently a hydrogen atom, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group.

It is preferred that A in at least one of the two Ls comprise a heteroaryl group or a heteroarylene group represented by the following formula (5):

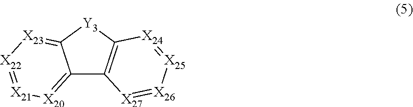

In the formula (5), X₂₀ to X₂₇ are independently N, CH, C(R₁₃) or a carbon atom that is bonded to L₁ or A;

R₁₃ is independently a single bond, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group, provided that if two adjacent groups of X₂₀ to X₂₇ are both C(R₁₃) and one of R₁₃s is a single bond, the single bond is used in the bond to the other R₁₃ to form a ring comprising the two carbon atoms.

Y₃ is O, S, NH, N(R₁₄) or a nitrogen atom that is bonded to L₁ or A;

R₁₄ is a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group.

It is preferred that n in one of the two Ls be 0. “n is 0” means that L₁ is not substituted by A in the formula (2).

An explanation will be made on examples of each group of the above-mentioned formulas (1) to (5).

In the specification of the present application, the aryl group includes a monocyclic aromatic hydrocarbon ring group and a fused aromatic hydrocarbon ring group obtained by fusing of a plurality of hydrocarbon rings, and the heteroaryl group includes a monocyclic heteroaromatic ring group, a hetero-fused aromatic ring group obtained by fusing a plurality of heteroaromatic rings and a hetero-fused aromatic ring group obtained by fusing of an aromatic hydrocarbon ring and a hetero aromatic ring.

The “unsubstituted” in the “substituted or unsubstituted” means substitution by a hydrogen atom, and the hydrogen atom in the material of the invention includes protium, deuterium and tritium.

Specific examples of the alkyl group having 1 to 20 carbon atoms include a methyl group, an ethyl group, a propyl group, an isopropyl group, an n-butyl group, an s-butyl group, an isobutyl group, a t-butyl group, an n-pentyl group, an n-hexy group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group and a 3-methylpentyl group. Of these, one having 1 to 6 carbon atoms is preferable.

As the alkoxy group having 1 to 20 carbon atoms, a methoxy group, an ethoxy group, a propoxy group, a butoxy group, a pentyloxy group, a hexyloxy group or the like can be given. Of these, as for one having 3 or more carbon atoms, it may be linear, cyclic or branched, and one having 1 to 6 carbon atoms is preferable.

Specific examples of the cycloalkyl group having 3 to 18 ring carbon atoms include a cyclopropyl group, a cyclobutyl group, a cyclopentyl group, a cyclohexy group, a cycloheptyl group, a norbonyl group and an adamantyl group. Of these, one having 5 or 6 ring carbon atoms is preferable.

Here, the “ring carbon atoms” means carbon atoms that constitute a saturated ring, an unsaturated ring or an aromatic ring.

As the cycloalkyl group having 3 to 18 ring carbon atoms, a cyclopentoxy group, a cyclohexyloxy group or the like can be given. Of these, one having 5 or 6 ring carbon atoms is preferable.

Specific examples of the aryl group having 6 to 18 ring carbon atoms include a phenyl group, a tolyl group, a xylyl group, a mesityl group, an o-biphenyl group, an m-biphenyl group, a p-biphenyl group, an o-terphenyl group, an m-terphenyl group, a p-terphenyl group, a naphthyl group, a phenanthryl group and a triphenylene group. Of these, a phenyl group is preferable.

As the aryloxy group having 6 to 18 ring carbon atoms, a phenoxy group and a biphenyloxy group or the like can be given, with a phenoxy group being preferable.

As the arylthio group having 6 to 18 ring carbon atoms, a phenylthio group, a biphenylthio group or the like can be given, with a phenylthio group being preferable.

Specific examples of the heteroaryl group having 5 to 18 ring atoms include a pyrrolyl group, a pyrazinyl group, a pyridinyl group, a pyrimidinyl group, a pyridazinyl group, a triazinyl group, an indolyl group, an isoindolyl group, a furyl group, a benzofuranyl group, an isobenzofuranyl group, a dibenzofuranyl group, a dibenzothiophenyl group, a quinolyl group, an isoquinolyl group, a quinoxalinyl group, a carbazolyl group, an azacarbazolyl group, a phenanthridinyl group, an acridinyl group, a phenanthrolinyl group, a thienyl group, a pyrrolidinyl group, a dioxanyl group, a piperidinyl group, a morpholinyl group, a piperazinyl group, a carbazolyl group, a thiophenyl group, an oxazolyl group, an oxadiazolyl group, a benzoxazolyl group, a thiazolyl group, a thiadiazolyl group, a benzothiazolyl group, a triazolyl group, an imidazolyl group, a benzimidazolyl group, a pyranyl group and a benzo[c]dibenzofuranyl group. Of these, one having 6 to 14 ring atoms is preferable.

In the meantime, the “ring atoms” mean atoms that constitute a saturated ring, an unsaturated ring or an aromatic ring.

Specific examples of the heteroaryloxy group having 5 to 18 ring atoms include a pyrrolyloxy group, a pyrazinyloxy group, a pyridinyloxy group, a pyrimidinyloxy group, a pyridazinyloxy group, a triazinyloxy group, an indolyloxy group, an isoindolyloxy group, a furyloxy group, a benzofuranyloxy group, an isobenzofuranyloxy group, a dibenzofuranyloxy group, a dibenzothiophenyloxy group, a quinolyloxy group, an isoquinolyloxy group, a quinoxalinyloxy group, a carbazolyloxy group, an azacarbazolyloxy group, a phenanthridinyloxy group, an acridinyloxy group, a phenanthrolinyloxy group, a thienyloxy group, a pyrrolidinyloxy group, a dioxanyloxy group, a piperidinyloxy group, a morpholinyloxy group, a piperazinyloxy group, a carbazolyloxy group, a thiophenyloxy group, an oxazolyloxy group, a oxadiazolyloxy group, a benzoxazolyloxy group, a thiazolyloxy group, a thiadiazolyloxy group, a benzothiazolyloxy group, a triazolyloxy group, an imidazolyloxy group, a benzimidazolyloxy group, a pyranyloxy group, and a benzo[c]dibenzofuranyloxy group. Of these, one having 6 to 14 ring carbon atoms is preferable.

Specific examples of the substituent when the aryl group, the aryloxy group, the heteroaryl group or the heteroaryloxy group has a substituent include a substituted or unsubstituted alkyl group, alkoxy group or fluoroalkyl group having 1 to 20 carbon atoms, a substituted or unsubstituted aryl group having 6 to 18 ring carbon atoms, a substituted or unsubstituted aryloxy group having 6 to 18 ring carbon atoms, a substituted or unsubstituted heteroaryl having 5 to 18 ring atoms, a substituted or unsubstituted heteroaryloxy group having 5 to 18 ring atoms, a substituted or unsubstituted aralkyl group having 7 to 30 carbon atoms, a halogen atom, a cyano group, a substituted or unsubstituted silyl group and a substituted or unsubstituted amino group.

As specific examples of the substituent if the alkyl group, the alkyloxy group, the cycloalkyl group and the cycloalkoxy group each have a substituent, those excluding from the aryl group, the aryloxy group and the heteroaryl group, an alkyl group having 1 to 20 carbon atoms, an alkyloxy group having 1 to 20 carbon atoms, a cycloalkyl group having 3 to 18 carbon atoms and a cycloalkyloxy group having 3 to 18 carbon atoms can be given.

Specific examples of the compound represented by the formula (1) are shown below.

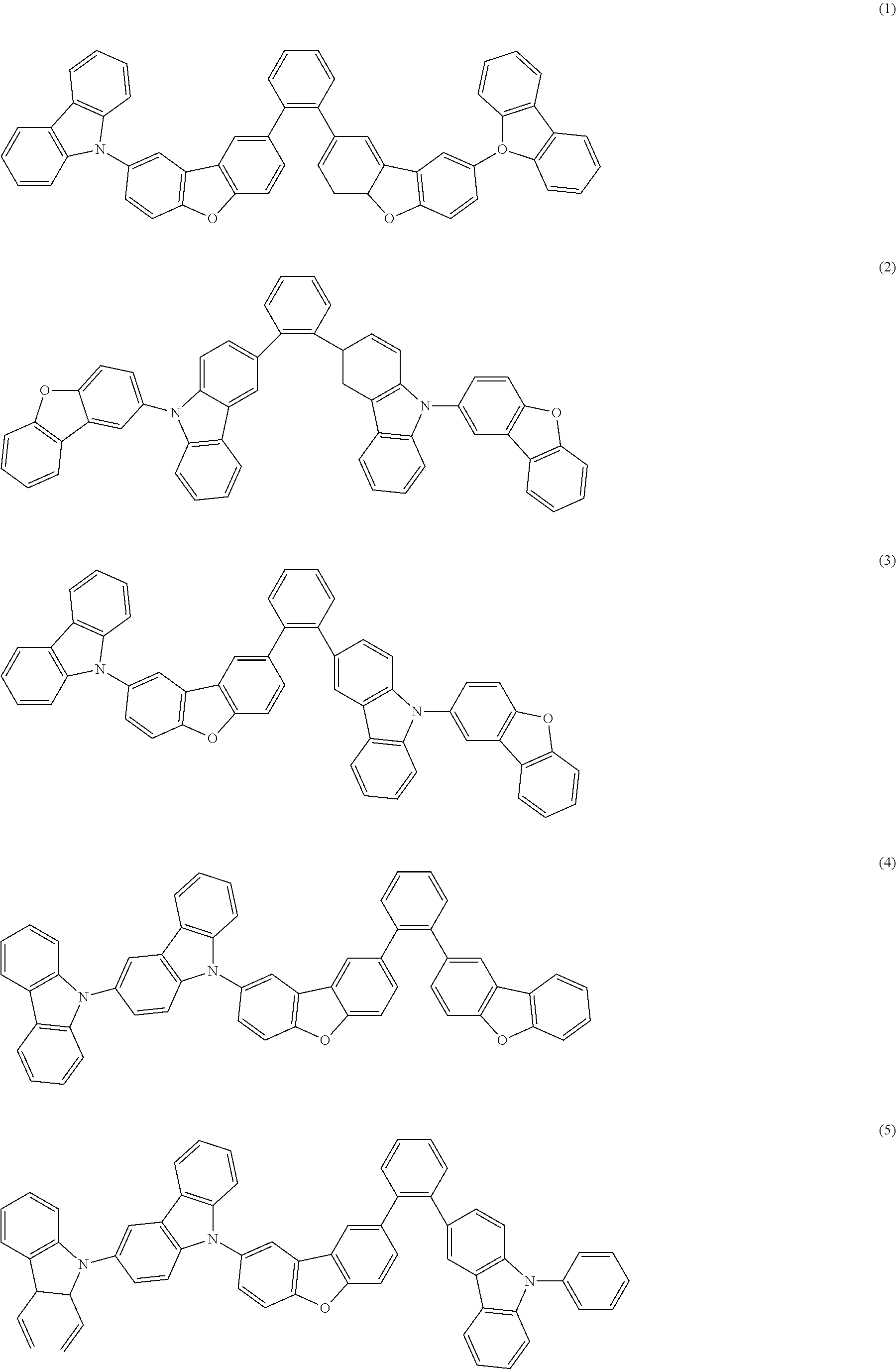

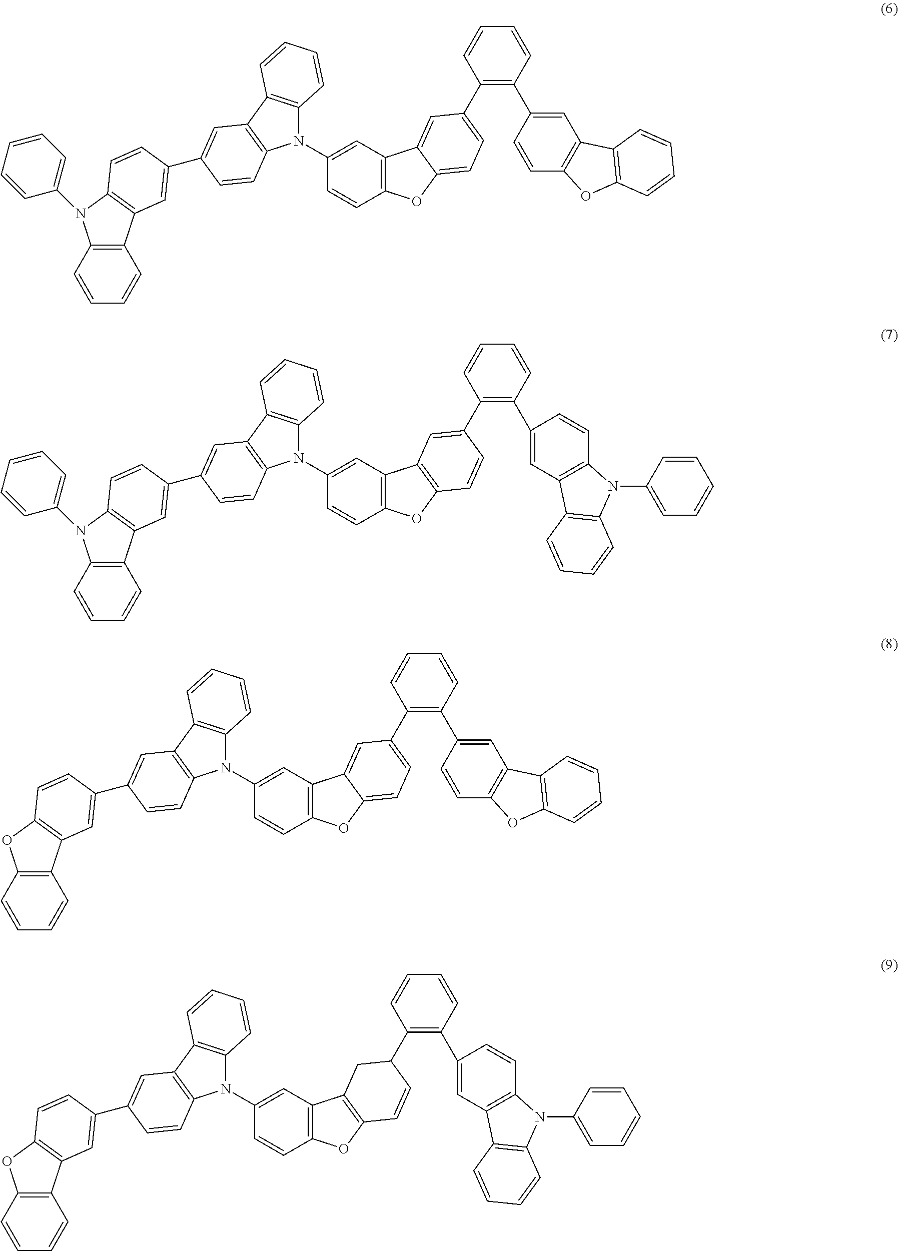 [SMILES: c1ccc(-n2c3ccccc3c3cc(-c4ccc5c(c4)c4ccccc4n5-c4ccc5oc6ccc(-c7ccccc7-c7ccc8oc9ccccc9c8c7)cc6c5c4)ccc32)cc1 ; c1ccc(-n2c3ccccc3c3cc(-c4ccc5c(c4)c4ccccc4n5-c4ccc5oc6ccc(-c7ccccc7-c7ccc8c(c7)c7ccccc7n8-c7ccccc7)cc6c5c4)ccc32)cc1 ; c1ccc(-c2ccc3oc4ccc(-n5c6ccccc6c6cc(-c7ccc8oc9ccccc9c8c7)ccc65)cc4c3c2)c(-c2ccc3oc4ccccc4c3c2)c1 ; C1=CC(c2ccccc2-c2ccc3c(c2)c2ccccc2n3-c2ccccc2)Cc2c1oc1ccc(-n3c4ccccc4c4cc(-c5ccc6oc7ccccc7c6c5)ccc43)cc21]

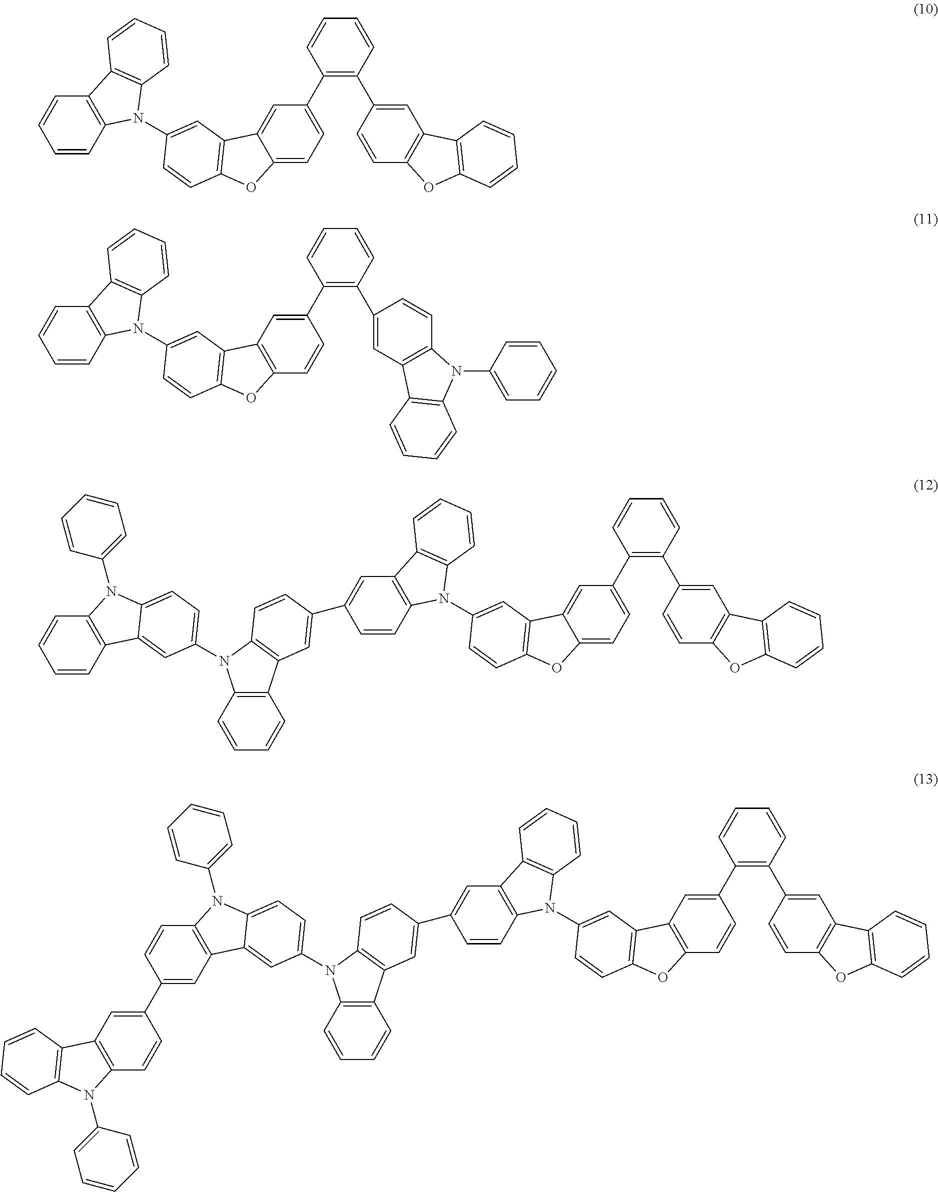

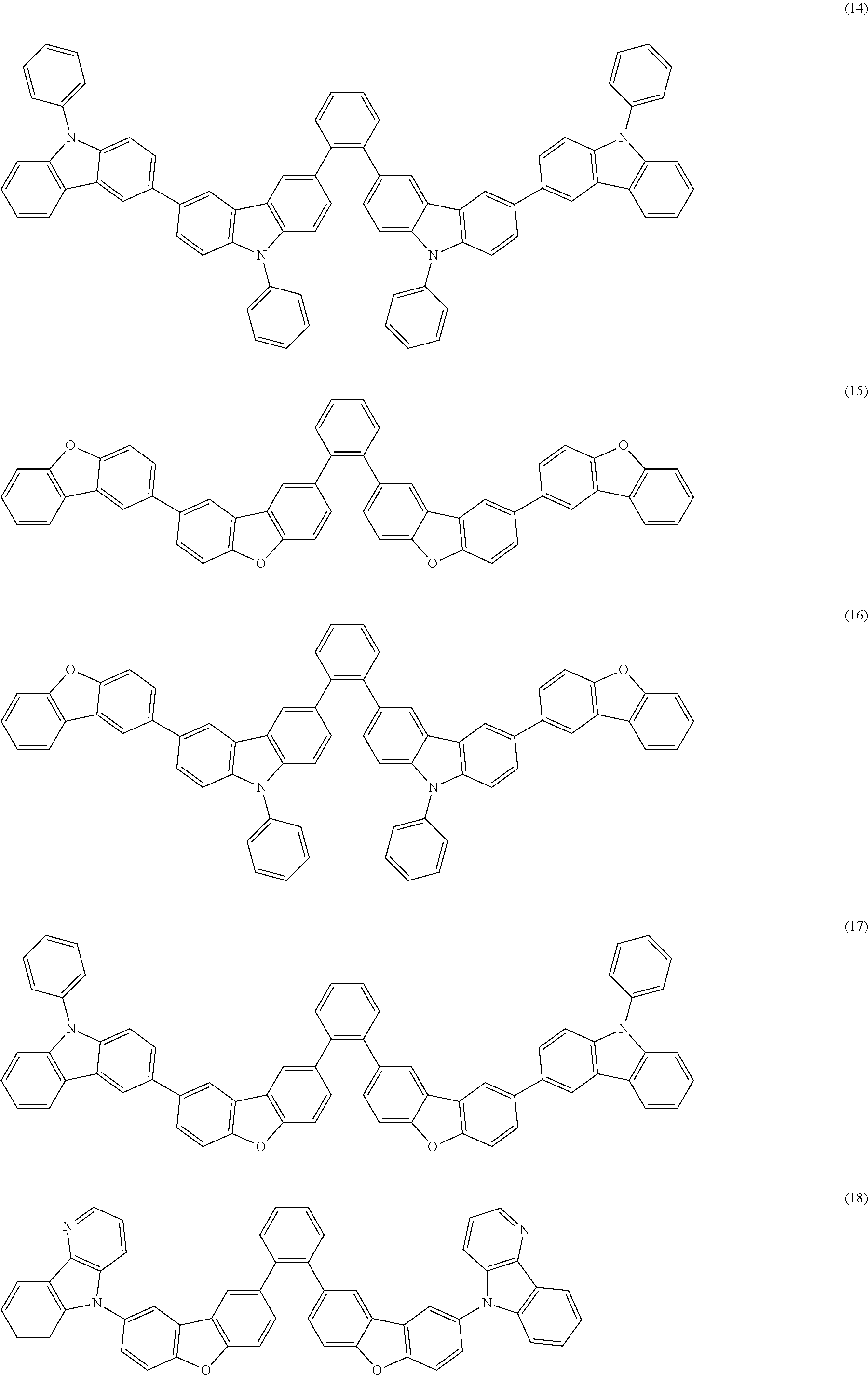

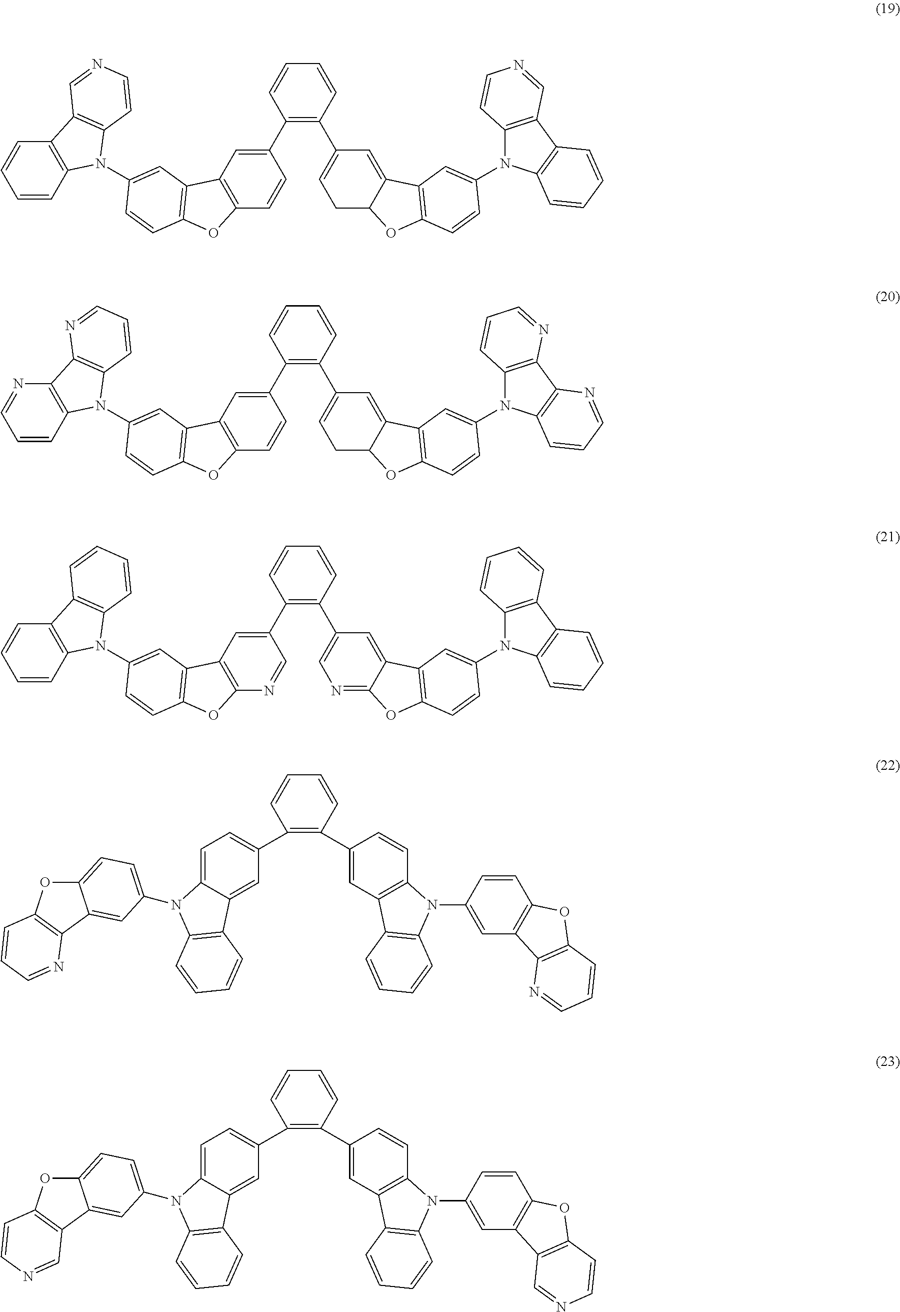 [SMILES: C1=C(c2ccccc2-c2ccc3oc4ccc(-n5c6ccccc6c6cnccc65)cc4c3c2)C=C2c3cc(-n4c5ccccc5c5cnccc54)ccc3OC2C1 ; C1=C(c2ccccc2-c2ccc3oc4ccc(-n5c6cccnc6c6ncccc65)cc4c3c2)C=C2c3cc(-n4c5cccnc5c5ncccc54)ccc3OC2C1 ; c1ccc(-c2cnc3oc4ccc(-n5c6ccccc6c6ccccc65)cc4c3c2)c(-c2cnc3oc4ccc(-n5c6ccccc6c6ccccc65)cc4c3c2)c1 ; c1ccc(-c2ccc3c(c2)c2ccccc2n3-c2ccc3oc4cccnc4c3c2)c(-c2ccc3c(c2)c2ccccc2n3-c2ccc3oc4cccnc4c3c2)c1 ; c1ccc(-c2ccc3c(c2)c2ccccc2n3-c2ccc3oc4ccncc4c3c2)c(-c2ccc3c(c2)c2ccccc2n3-c2ccc3oc4ccncc4c3c2)c1]

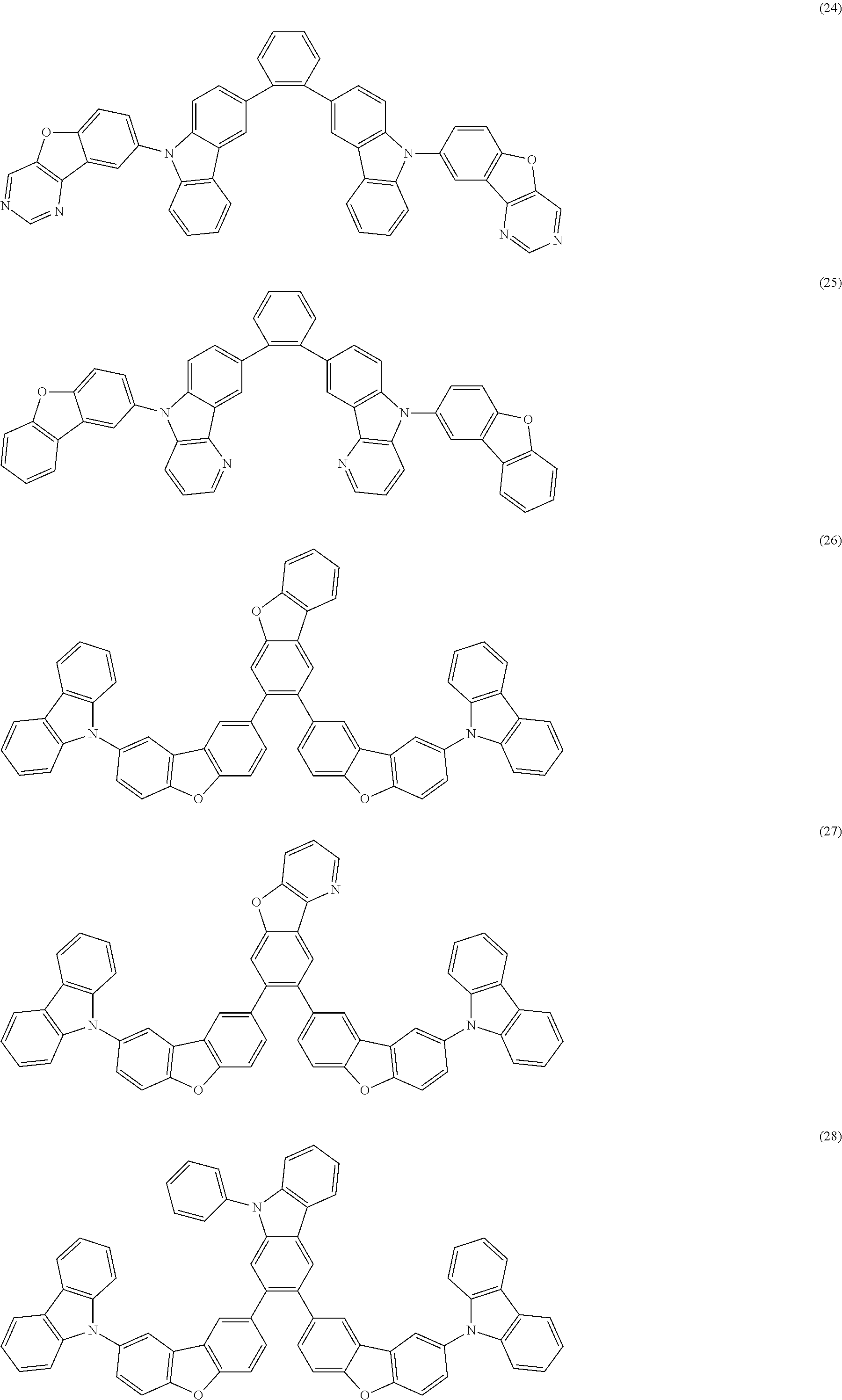

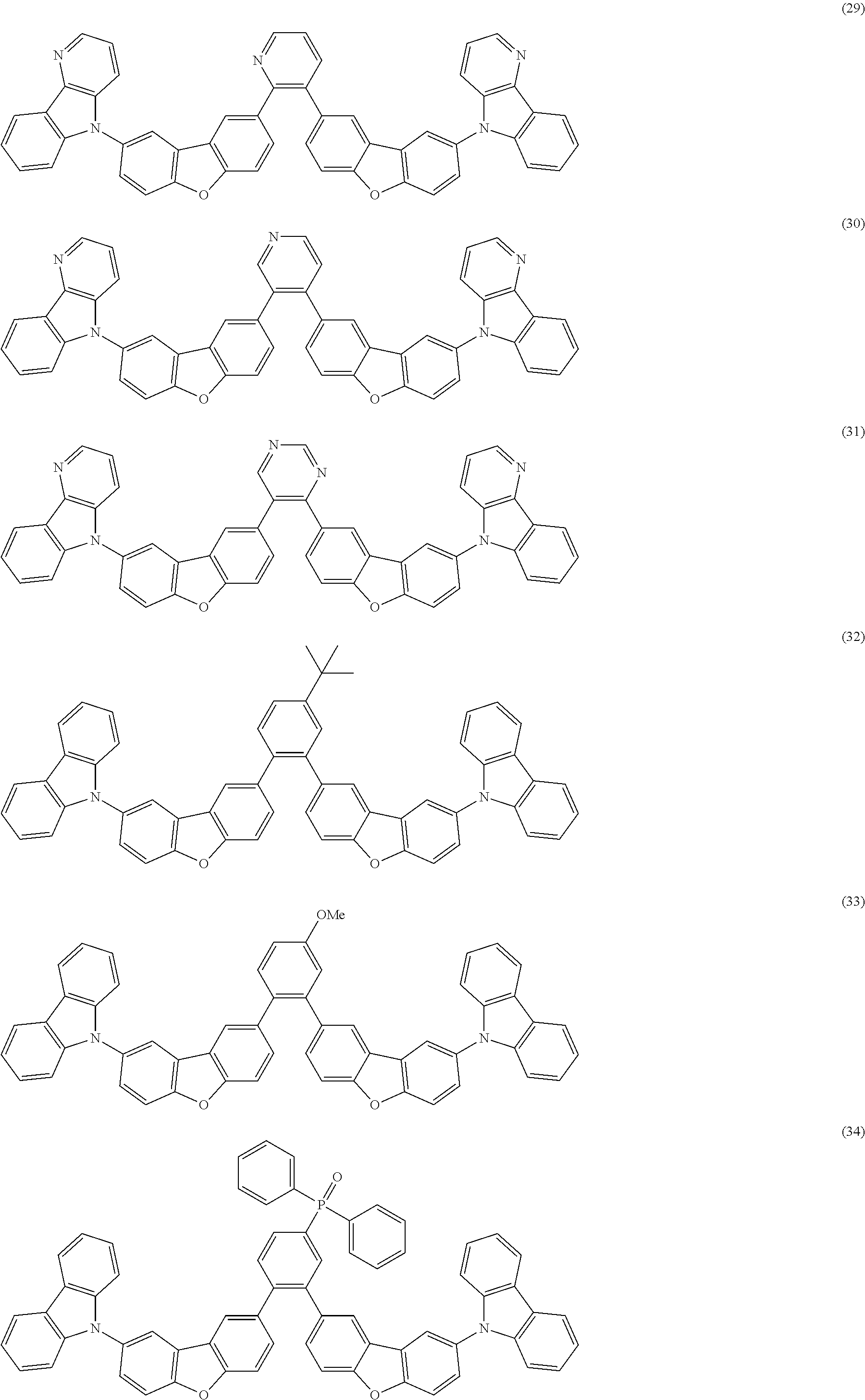

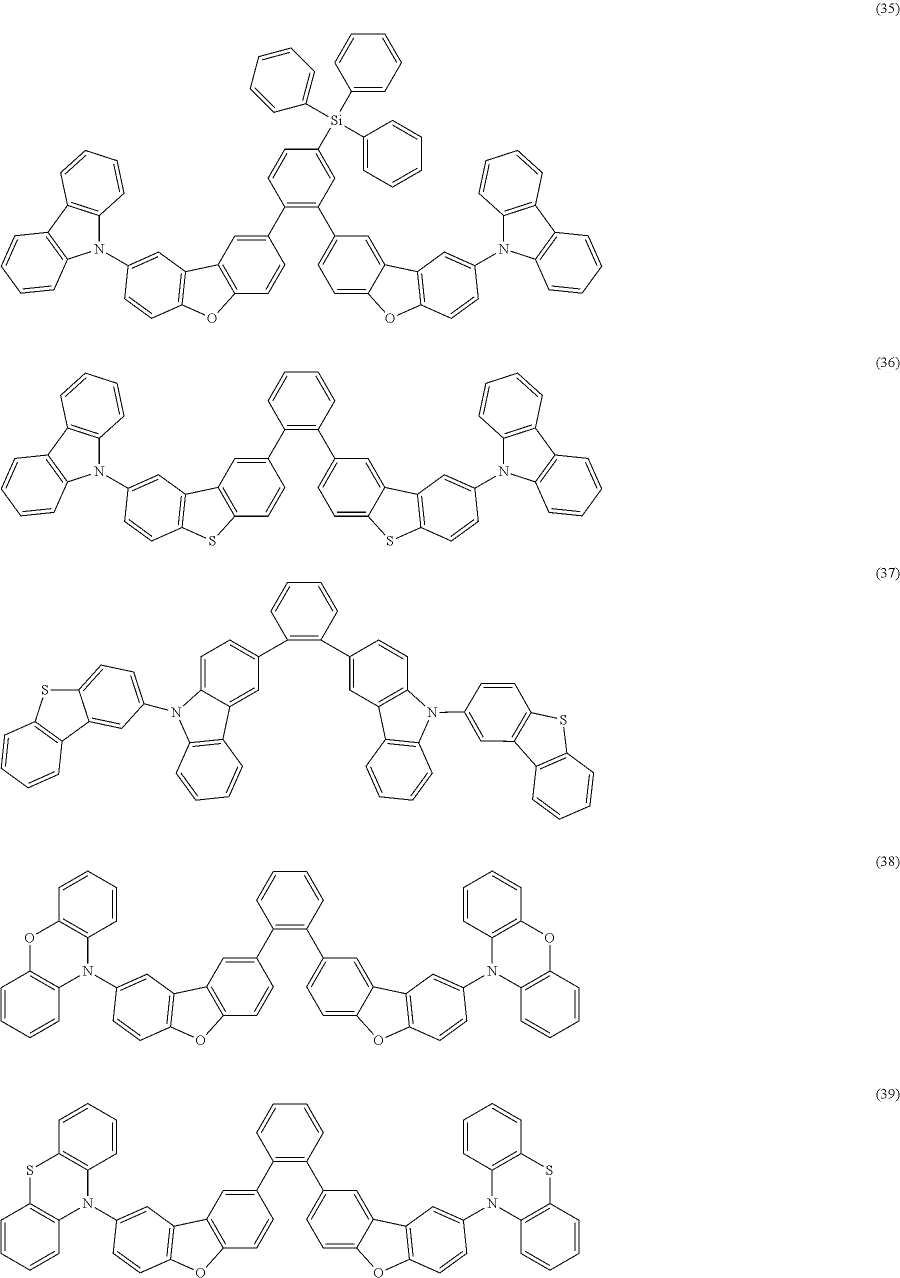

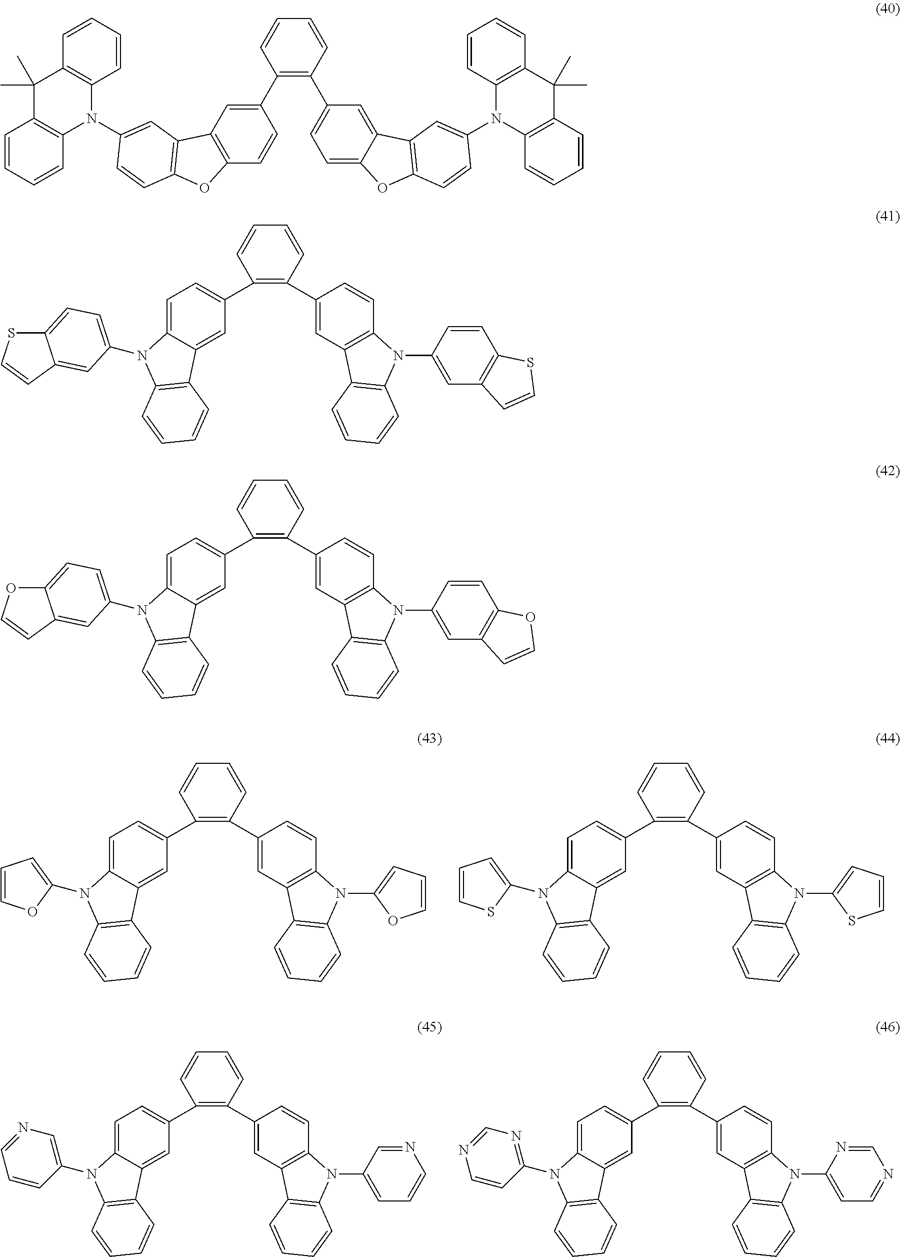

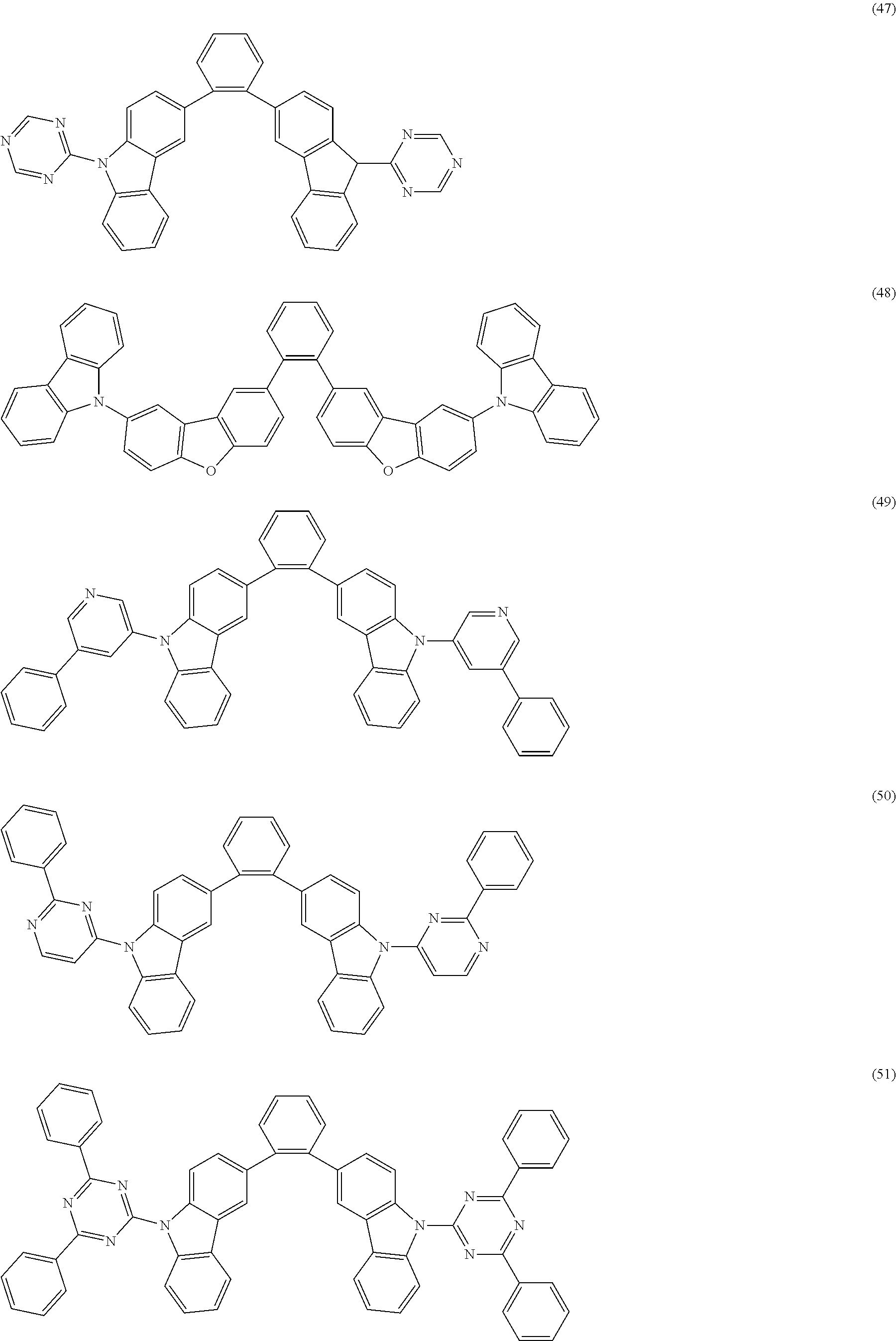 [SMILES: c1ccc(-c2ccc3c(c2)c2ccccc2n3-c2ncncn2)c(-c2ccc3c(c2)-c2ccccc2C3c2ncncn2)c1 ; c1ccc(-c2ccc3oc4ccc(-n5c6ccccc6c6ccccc65)cc4c3c2)c(-c2ccc3oc4ccc(-n5c6ccccc6c6ccccc65)cc4c3c2)c1 ; c1ccc(-c2cncc(-n3c4ccccc4c4cc(-c5ccccc5-c5ccc6c(c5)c5ccccc5n6-c5cncc(-c6ccccc6)c5)ccc43)c2)cc1 ; c1ccc(-c2nccc(-n3c4ccccc4c4cc(-c5ccccc5-c5ccc6c(c5)c5ccccc5n6-c5ccnc(-c6ccccc6)n5)ccc43)n2)cc1 ; c1ccc(-c2nc(-c3ccccc3)nc(-n3c4ccccc4c4cc(-c5ccccc5-c5ccc6c(c5)c5ccccc5n6-c5nc(-c6ccccc6)nc(-c6ccccc6)n5)ccc43)n2)cc1]

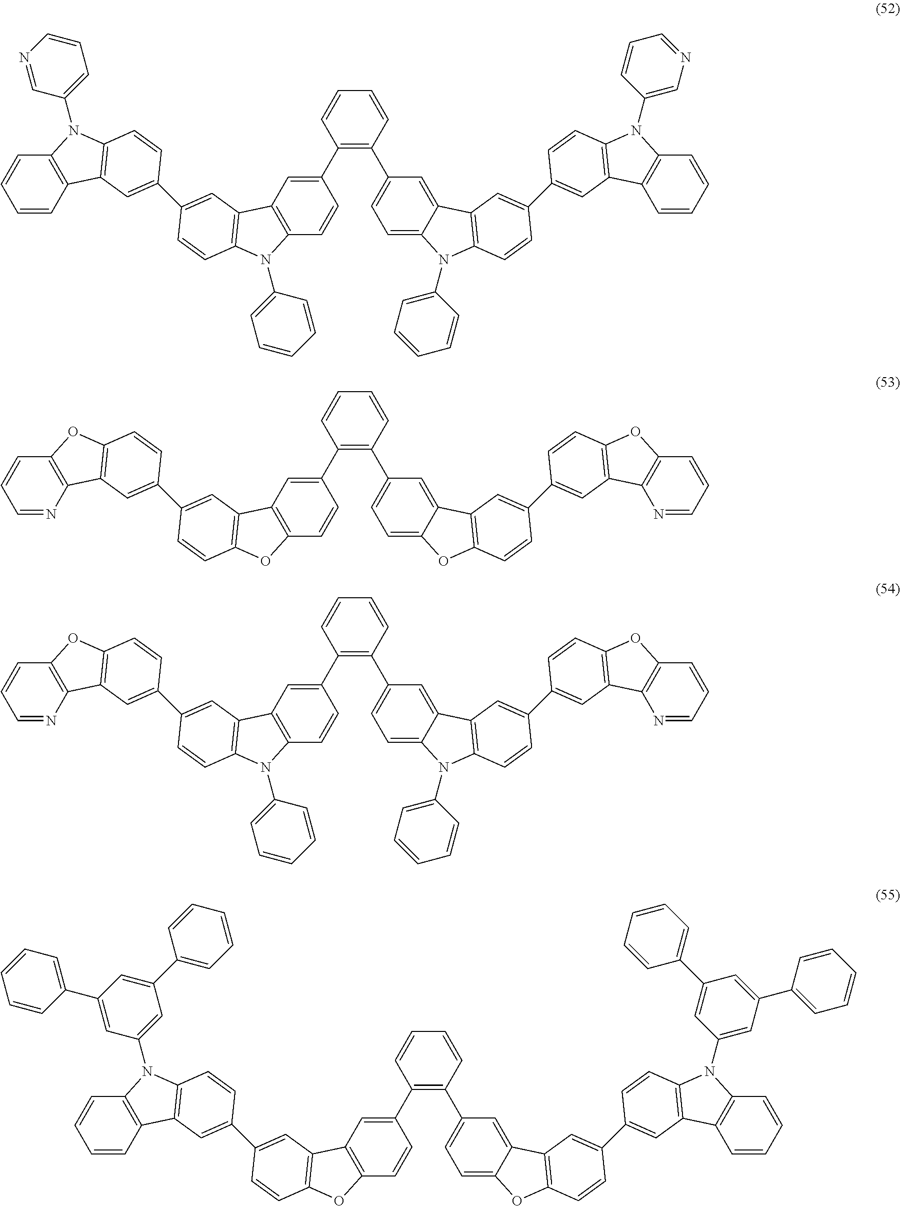

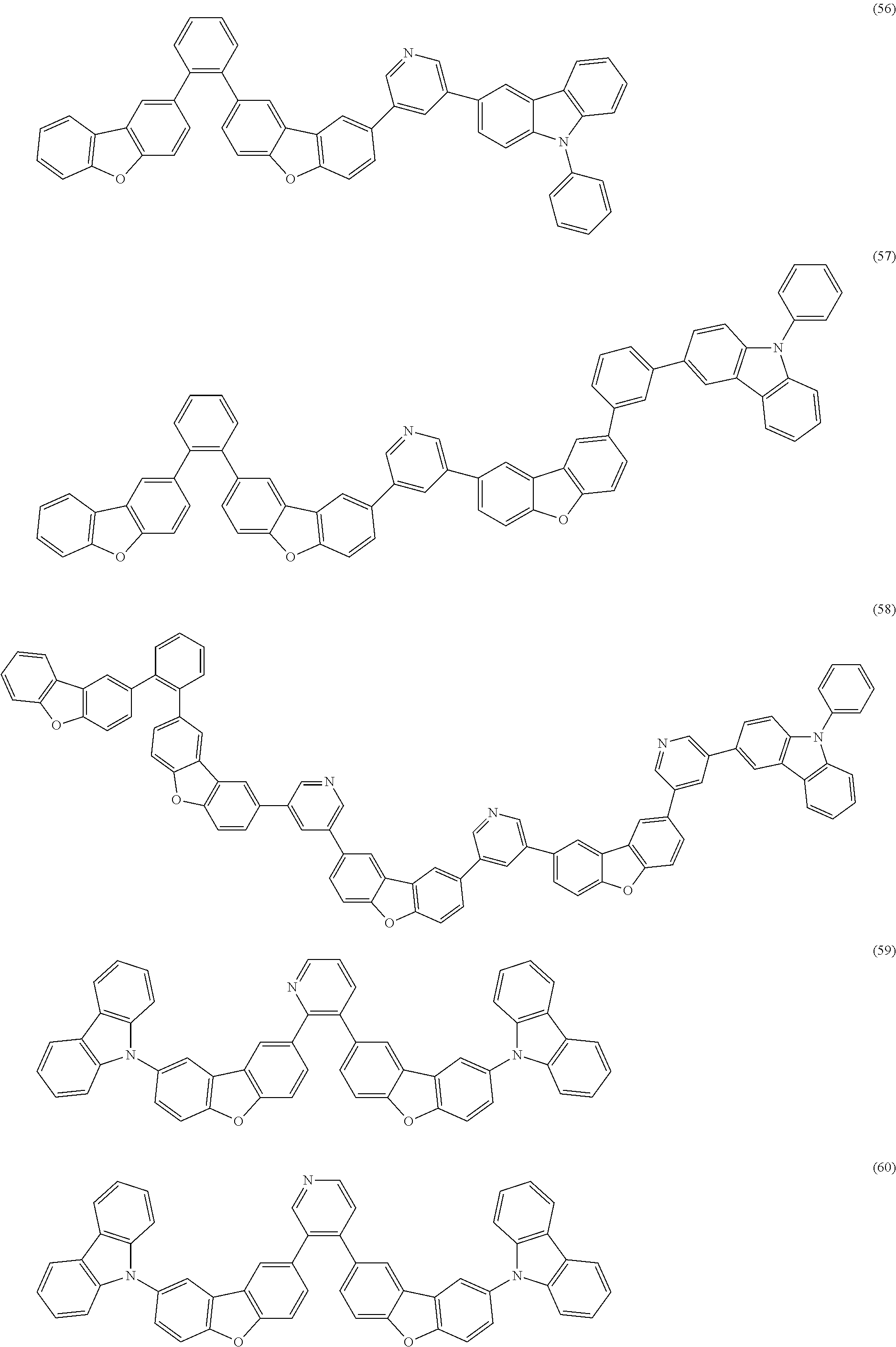

The material for an organic electroluminescence device (organic EL device) of the invention (hereinafter often referred to as the “material of the invention”) is characterized by containing the above-mentioned compound of the invention.

The material for an organic EL device of the invention can preferably be used as the material of organic thin film layers constituting an organic EL device.

Subsequently, an explanation will be made on the organic EL device of the invention.

The organic EL device of the invention comprises one or more organic thin film layers including an emitting layer between an anode and a cathode. At least one of the organic thin film layers comprises the material for an organic EL device of the invention.

In the organic EL device of the invention, it is preferred that the emitting layer contain the material for an organic EL device of the invention as a host material.

It is preferred that the emitting layer comprise a phosphorescent emitting material which is an ortho-metalated complex of a metal atom selected from iridium (Ir), osmium (Os) and platinum (Pt).

In the organic EL device of the invention, it is preferred that an electron-transporting region be provided between the cathode and the emitting layer and that the electron-transporting region comprise the material for an organic EL device of the invention.

An electron-injecting layer is preferably provided between the emitting layer and the cathode, and the electron-injecting layer preferably comprises a nitrogen-containing ring derivative.

A hole-transporting region is preferably provided between the emitting layer and the anode, and the hole-transporting region preferably comprises the material for an organic EL device.

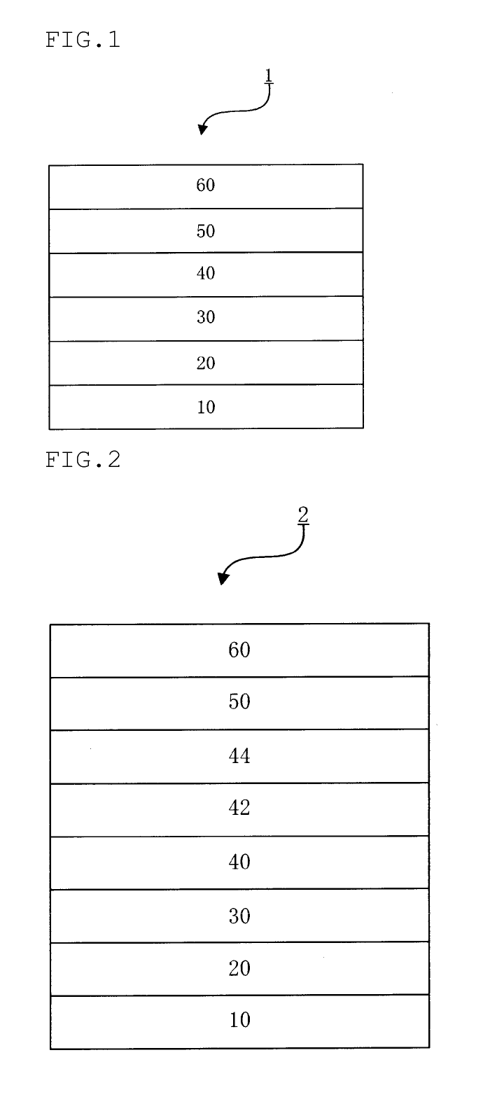

FIG. 1 is a schematic view showing the layer structure according to one embodiment of the organic EL device of the invention.

An organic EL device 1 has a configuration in which an anode 20, a hole-transporting region 30, a phosphorescent emitting layer 40, an electron-transporting region 50, and a cathode 60 are sequentially stacked on a substrate 10. The hole-transporting region 30 refers to as a hole-transporting layer, a hole-injecting layer, and the like. The electron-transporting region 50 refers to as an electron-transporting layer, an electron-injecting layer, and the like. The hole-transporting layer and the like need not necessarily be formed, but it is preferable to form one or more hole-transporting layers and the like. In this device, each organic layer included in the hole-transporting region 30, the phosphorescent emitting layer 40, and each organic layer included in the electron-transporting region 50 are organic thin film layers. At least one organic thin film layer among these organic thin film layers includes the material for an organic EL device according to the invention. This makes it possible to reduce the driving voltage of the organic EL device.

The content of the material for an organic EL device according to the invention in the at least one organic thin film layer is preferably 1 to 100 wt %.

In the organic EL device according to the invention, it is preferable that the phosphorescent emitting layer 40 include the material for an organic EL device according to the invention. It is particularly preferable to use the material for an organic EL device according to the invention as a host material for the emitting layer. Since the material according to the invention has a sufficiently high triplet energy, the triplet energy of a phosphorescent dopant material can be efficiently confined in the emitting layer even when using a blue phosphorescent dopant material. Note that the material according to the invention may also be used for an emitting layer that emits light (e.g. green to red) having a wavelength longer than that of blue light.

The phosphorescent emitting layer includes a phosphorescent material (phosphorescent dopant). Examples of the phosphorescent dopant include metal complex compounds. It is preferable to use a compound that includes a metal atom selected from Ir, Pt, Os, Au, Cu, Re, and Ru, and a ligand. It is preferable that the ligand have an orthometal bond.

It is preferable that the phosphorescent dopant be a compound that includes a metal atom selected from Ir, Os, and Pt, more preferably a metal complex such as an iridium complex, an osmium complex, or a platinum complex, still more preferably an iridium complex or a platinum complex, and most preferably an ortho-metalated iridium complex, since the external quantum efficiency of the device can be improved due to high phosphorescence quantum yield. These dopants may be used either alone or in combination of two or more.

The concentration of the phosphorescent dopant in the phosphorescent emitting layer is not particularly limited, but is preferably 0.1 to 30 wt %, and still more preferably 0.1 to 20 wt %.

It is also preferable to use the material according to the invention for a layer adjacent to the phosphorescent emitting layer 40. For example, when a layer (anode-side adjacent layer) that includes the material according to the invention is formed between the hole-transporting region 30 and the phosphorescent emitting layer 40 included in the device illustrated in FIG. 1, the layer that includes the material according to the invention functions as an electron barrier layer or an exciton blocking layer.

When a layer (cathode-side adjacent layer) that includes the material according to the invention is formed between the phosphorescent emitting layer 40 and the electron-transporting region 50, the layer that includes the material according to the invention functions as a hole barrier layer or an exciton blocking layer.

Note that the term “barrier layer (blocking layer)” used herein refers to a layer that functions as a carrier migration barrier or an exciton diffusion barrier. An organic layer for preventing leakage of electrons from the emitting layer to the hole-transporting region may be referred to as “electron barrier layer”, and an organic layer for preventing leakage of holes from the emitting layer to the electron-transporting region may be referred to as “hole barrier layer”. An organic layer for preventing diffusion of triplet excitons generated in the emitting layer into a peripheral layer that has a triplet energy level lower than that of the emitting layer may be referred to as “exciton blocking layer (triplet barrier layer)”.

The material according to the invention may also be used for a layer adjacent to the phosphorescent emitting layer 40 and another organic thin film layer that is bonded to the layer adjacent to the phosphorescent emitting layer 40.

When forming two or more emitting layers, the material according to the invention may suitably be used for forming a space layer that is formed between the emitting layers.

FIG. 2 is a schematic view illustrating the layer configuration of an organic EL device according to another embodiment of the invention.

An organic EL device 2 illustrated in FIG. 2 is an example of a hybrid organic EL device in which a phosphorescent emitting layer and a fluorescent emitting layer are stacked.

The organic EL device 2 is configured in the same manner as the organic EL device 1, except that a space layer 42 and a fluorescent emitting layer 44 are formed between a phosphorescent emitting layer 40 and a electron-transporting region 50. When the phosphorescent emitting layer 40 and the fluorescent emitting layer 44 are stacked, the space layer 42 may be provided between the fluorescent emitting layer 44 and the phosphorescent emitting layer 40 so that excitons formed in the phosphorescent emitting layer 40 are not diffused into the fluorescent emitting layer 44. The material according to the invention can function as the space layer due to a high triplet energy.

The organic EL device 2 emits white light when the phosphorescent emitting layer is a yellow emitting layer, and the fluorescent emitting layer is a blue emitting layer, for example. Although an example in which one phosphorescent emitting layer and one fluorescent emitting layer are formed has been described above, two or more phosphorescent emitting layers and/or two or more fluorescent emitting layers may be formed. The number of phosphorescent emitting layers and the number of fluorescent emitting layers may be appropriately set depending on the application (e.g., illumination (lighting) or display). For example, when forming a full-color emitting device by utilizing a white emitting device and a color filter, it may be preferable that the device include layers that differ in emission wavelength region (e.g., red, green, and blue (RGB), or red, green, blue, and yellow (RGBY)) from the viewpoint of color rendering properties.

In addition to the above-mentioned embodiment, the organic EL device of the invention can have various known structures. Emission of the emitting layer can be outcoupled from the anode, the cathode, or both.

### (Electron-Donating Dopant and Organic Metal Complex)

It is preferable that the organic EL device according to the invention include at least one of an electron donor dopant and an organic metal complex in the interface region between the cathode and the organic thin film layer.

The above configuration makes it possible to improve the luminance and the lifetime of the organic EL device.

The electron donor dopant may be at least one metal or compound selected from alkali metals, alkali metal compounds, alkaline-earth metals, alkaline-earth metal compounds, rare-earth metals, rare-earth metal compounds, and the like.

The organic metal complex may be at least one organic metal complex selected from alkali metal-containing organic metal complexes, alkaline-earth metal-containing organic metal complexes, rare-earth metal-containing organic metal complexes, and the like.

Examples of the alkali metals include lithium (Li) (work function: 2.93 eV), sodium (Na) (work function: 2.36 eV), potassium (K) (work function: 2.28 eV), rubidium (Rb) (work function: 2.16 eV), cesium (Cs) (work function: 1.95 eV), and the like. It is particularly preferable to use an alkali metal having a work function of 2.9 eV or less. Among these, K, Rb, and Cs are preferable, Rb and Cs are more preferable, and Cs is most preferable.

Examples of the alkaline-earth metals include calcium (Ca) (work function: 2.9 eV), strontium (Sr) (work function: 2.0 to 2.5 eV), barium (Ba) (work function: 2.52 eV), and the like. It is particularly preferable to use an alkaline-earth metal having a work function of 2.9 eV or less.

Examples of the rare-earth metals include scandium (Sc), yttrium (Y), cerium (Ce), terbium (Tb), ytterbium (Yb), and the like. It is particularly preferable to use a rare-earth metal having a work function of 2.9 eV or less.

Since the above preferable metals exhibit a particularly high reducing capability, the luminance and the lifetime of the organic EL device can be improved by adding a relatively small amount of such a metal to the electron-injecting region.

Examples of the alkali metal compounds include alkali metal oxides such as lithium oxide (Li₂O), cesium oxide (Cs₂O), and potassium oxide (K₂O), alkali halides such as lithium fluoride (LiF), sodium fluoride (NaF), cesium fluoride (CsF), and potassium fluoride (KF), and the like. Among these, lithium fluoride (LiF), lithium oxide (Li₂O), and sodium fluoride (NaF) are preferable.

Examples of the alkaline-earth metal compounds include barium oxide (BaO), strontium oxide (SrO), calcium oxide (CaO), mixtures thereof (e.g., barium strontium oxide (BaSr₁₋ₓO) (0<x<1) and (BaₓCa₁₋ₓO) (0<x<1)), and the like. Among these, BaO, SrO, and CaO are preferable.

Examples of the rare-earth metal compounds include ytterbium fluoride (YbF₃), scandium fluoride (ScF₃), scandium oxide (ScO₃), yttrium oxide (Y₂O₃), cerium oxide (Ce₂O₃), gadolinium fluoride (GdF₃), terbium fluoride (TbF₃), and the like. Among these, YbF₃, ScF₃, and TbF₃ are preferable.

The organic metal complex is not particularly limited as long as the organic metal complex includes at least one of an alkali metal ion, an alkaline-earth metal ion, and rare-earth metal ion as the metal ion. Examples of a preferable ligand include, but are not limited to, quinolinol, benzoquinolinol, acridinol, phenanthridinol, hydroxyphenyloxazole, hydroxyphenylthiazole, hydroxydiaryloxadiazoles, hydroxydiarytthiadiazoles, hydroxyphenylpyridine, hydroxyphenylbenzimidazole, hydroxybenzotriazole, hydroxyfluborane, bipyridyl, phenanthroline, phthalocyanine, porphyrin, cyclopentadiene, 1-diketones, azomethines, derivatives thereof, and the like.

The electron donor dopant and the organic metal complex are preferably deposited (formed) in the interface region in the shape of a layer or islands. It is preferable to deposit an organic substance (i.e., an emitting material or an electron-injecting material that forms the interface region) while depositing at least one of the electron donor dopant and the organic metal complex by resistance heating deposition so that at least one of the electron donor dopant and the organic metal complex reducing dopant is dispersed in the organic material. The dispersion concentration (i.e., the molar ratio of the organic substance to the electron donor dopant and/or the organic metal complex) is normally 100:1 to 1:100, and preferably 5:1 to 1:5.

When depositing (forming) at least one of the electron donor dopant and the organic metal complex in the shape of a layer, the emitting material or the electron-injecting material (i.e., the organic layer at the interface) is deposited (formed) in the shape of a layer, and at least one of the electron donor dopant and the organic metal complex is deposited singly by resistance heating deposition to a thickness of preferably 0.1 nm to 15 nm.

When depositing (forming) at least one of the electron donor dopant and the organic metal complex in the shape of islands, the emitting material or the electron-injecting material (i.e., the organic layer at the interface) is deposited (formed) in the shape of islands, and at least one of the electron donor dopant and the organic metal complex is deposited singly by resistance heating deposition to a thickness of preferably 0.05 nm to 1 nm.

The ratio of the main component (an emitting material or an electron-injecting material) to at least one of the electron donor dopant and/or the organic metal complex in the organic EL device according to the invention is preferably 5:1 to 1:5, and further preferably 2:1 to 1:2.

In the organic EL device according to the invention, the configuration other than the layer formed using the material for an organic EL device according to the invention is not particularly limited. The layers other than the layer formed using the material for an organic EL device according to the invention may be formed using a known material and the like. Hereinbelow, a brief explanation will be made on the layer of the embodiment 1. The material to be used in the organic EL device of the invention is not restricted to those mentioned below.

### [Substrate]

A glass sheet, a polymer sheet, or the like may be used as the substrate.

Examples of a material for forming the glass sheet include soda lime glass, barium-strontium-containing glass, lead glass, aluminosilicate glass, borosilicate glass, barium borosilicate glass, quartz, and the like. Examples of a material for forming the polymer sheet include polycarbonate, acryl, polyethylene terephthalate, polyethersulfone, polysulfone, and the like.

### [Anode]

The anode is formed of a conductive material, for example. It is preferable to use a conductive material having a work function of more than 4 eV.

Examples of the conductive material include carbon, aluminum, vanadium, iron, cobalt, nickel, tungsten, silver, gold, platinum, palladium, alloys thereof, metal oxides (e.g., tin oxide and indium oxide) used for an ITO substrate and an NESA substrate, organic conductive resins (e.g., polythiophene and polypyrrole), and the like.

The anode may optionally be formed of two or more layers.

### [Cathode]

The cathode is formed of a conductive material, for example. It is preferable to use a conductive material having a work function of less than 4 eV.

Examples of the conductive material include, but are not limited to, magnesium, calcium, tin, lead, titanium, yttrium, lithium, ruthenium, manganese, aluminum, lithium fluoride, alloys thereof, and the like.

Examples of the alloys include, but are not limited to, a magnesium/silver alloy, a magnesium/indium alloy, a lithium/aluminum alloy, and the like. The alloy ratio is appropriately selected depending on the temperature of the deposition source, the atmosphere, the degree of vacuum, and the like.

The cathode may optionally be formed by two or more layers. The cathode may be formed by forming a thin film of the conductive material by deposition, sputtering, or the like.

When outcoupling light from the emitting layer through the cathode, it is preferable that the cathode have a light transmittance of more than 10%.

The sheet resistance of the cathode is preferably several hundred Ω/square or less. The thickness of the cathode is normally 10 nm to 1 μm, and preferably 50 to 200 nm.

### [Emitting Layer]

When forming the phosphorescent emitting layer using a material other than the material for an organic EL device according to the invention, a known material may be used as the material for forming the phosphorescent emitting layer. Japanese Patent Application No. 2005-517938 and the like disclose specific examples of the materials for forming the phosphorescent emitting layer.

The organic EL device according to the invention may include a fluorescent emitting layer (see the device shown FIG. 2). The fluorescent emitting layer may be formed using a known material.

The emitting layer may have a double-host (host-cohost) configuration. More specifically, the carrier balance within the emitting layer may be adjusted by incorporating an electron-transporting host and a hole-transporting host in the emitting layer.

The emitting layer may also have a double-dopant configuration. When the emitting layer includes two or more dopant materials having a high quantum yield, each dopant emits light. For example, a yellow emitting layer may be implemented by co-depositing a host, a red dopant, and a green dopant.

The emitting layer may include only a single layer, or may have a stacked structure. When the emitting layer has a stacked structure, the recombination region can be concentrated at the interface between the stacked layers due to accumulation of electrons and holes there. This makes it possible to improve the quantum efficiency.

### [Hole-Injecting Layer and Hole-Transporting Layer]

The hole-injecting/transporting layer is a layer that assists injection of holes into the emitting layer, and transports holes to the emitting region. The hole-injecting/transporting layer exhibits a high hole mobility, and normally has a low ionization energy of 5.6 eV or less.

It is preferable to form the hole-injecting/transporting layer using a material that transports holes to the emitting layer at a low field intensity. It is more preferable to use a material having a hole mobility of at least 10⁴ cm²N/V·s when an electric field of 10⁴ to 10⁶ V/cm is applied, for example.

Specific examples of the material for forming the hole-injecting/transporting layer include triazole derivatives (see U.S. Pat. No. 3,112,197, for example), oxadiazole derivatives (see U.S. Pat. No. 3,189,447, for example), imidazole derivatives (see JP-B-37-16096, for example), polyarylalkane derivatives (see U.S. Pat. No. 3,615,402, U.S. Pat. No. 3,820,989, U.S. Pat. No. 3,542,544, JP-B-45-555, JP-B-51-10983, JP-A-51-93224, JP-A-55-17105, JP-A-56-4148, JP-A-55-108667, JP-A-55-156953, and JP-A-56-36656, for example), pyrazoline derivatives and pyrazolone derivatives (U.S. Pat. No. 3,180,729, U.S. Pat. No. 4,278,746, JP-A-55-88064, JP-A-55-88065, JP-A-49-105537, JP-A-55-51086, JP-A-56-80051, JP-A-56-88141, JP-A-57-45545, JP-A-54-112637, and JP-A-55-74546, for example), phenylenediamine derivatives (U.S. Pat. No. 3,615,404, JP-B-51-10105, JP-B-46-3712, JP-B-47-25336, and JP-B-54-119925, for example), arylamine derivatives (U.S. Pat. No. 3,567,450, U.S. Pat. No. 3,240,597, U.S. Pat. No. 3,658,520, U.S. Pat. No. 4,232,103, U.S. Pat. No. 4,175,961, U.S. Pat. No. 4,012,376, JP-B-49-35702, JP-B-39-27577, JP-A-55-144250, JP-A-56-119132, JP-A-56-22437, and West German Patent No. 1,110,518, for example), amino-substituted chaicone derivatives (U.S. Pat. No. 3,526,501, for example), oxazole derivatives (see U.S. Pat. No. 3,257,203, for example), styrylanthracene derivatives (JP-A-56-46234, for example), fluorenone derivatives (JP-A-54-110837, for example), hydrazone derivatives (U.S. Pat. No. 3,717,462, JP-A-54-59143, JP-A-55-52063, JP-A-55-52064, JP-A-55-46760, JP-A-57-11350, JP-A-57-148749, and JP-A-2-311591, for example), stilbene derivatives (JP-A-61-210363, JP-A-61-228451, JP-A-61-14642, JP-A-61-72255, JP-A-62-47646, JP-A-62-36674, JP-A-62-10652, JP-A-62-30255, JP-A-60-93455, JP-A-60-94462, JP-A-60-174749, and JP-A-60-175052, for example), silazane derivatives (U.S. Pat. No. 4,950,950, for example), polysilane compounds (JP-A-2-204996, for example), aniline copolymers (JP-A-2-282263, for example), and the like.

An inorganic compound (e.g., p-type Si or p-type SiC) may also be used as the hole-injecting material.

A crosslinkable material may be used as the material for forming the hole-injecting/transporting layer. Examples of the crosslinkable hole-injecting/transporting layer include layers obtained by insolubilizing crosslinkable materials disclosed in Chem. Mater. 2008, 20, pp. 413-422, Chem. Mater. 2011, 23 (3), pp. 658-681, WO2008/108430, WO2009/102027, WO2009/123269, WO2010/016555, WO2010/018813, and the like by applying heat, light, and the like.

### [Electron-Injecting Layer and Electron-Transporting Layer]

The electron injecting/transporting layer is a layer that assists injection of electrons into the emitting layer, and transports electrons to the emitting region. The electron injecting/transporting layer exhibits high electron mobility.

Since an organic EL device is designed so that emitted light is reflected by an electrode (e.g., cathode), light that is outcoupled directly through the anode interferes with light that is outcoupled after being reflected by the electrode. The thickness of the electron-injecting/transporting layer is appropriately selected within the range of several nanometers to several micrometers in order to efficiently utilize the above interference effect. In particular, when the electron-injecting/transporting layer has a large thickness, it is preferable that the electron mobility be at least 10⁻⁵ cm²/Vs or more at an applied electric field of 10⁴ to 10⁶ V/cm in order to prevent an increase in voltage.

A aromatic heterocyclic compound having one or more hetero atoms in the molecule is preferably used as an electron-transporting material used for forming the electron-injecting/transporting layer. It is particularly preferable to use a nitrogen-containing ring derivative. An aromatic compound having a nitrogen-containing 6-membered or 5-membered ring skeleton, or a fused aromatic compound having a nitrogen-containing 6-membered or 5-membered ring skeleton is preferable as the nitrogen-containing ring derivative. Examples of such compounds include compounds that include a pyridine ring, a pyrimidine ring, a triazine ring, a benzimidazole ring, a phenanthroline ring, a quinazoline ring, or the like in the skeleton.

An organic layer that exhibits semiconductivity may be formed by doping (n) with a donor material and doping (p) with an acceptor material. Typical examples of N-doping include doping an electron-transporting material with a metal such as Li or Cs, and typical examples of P-doping include doping a hole-transporting material with an acceptor material such as F4TCNQ (see Japanese Patent No. 3695714, for example).

Each layer of the organic EL device according to the invention may be formed by a known method, e.g., a dry film-forming method such as vacuum deposition, sputtering, plasma coating, or ion plating, or a wet film-forming method such as spin coating, dipping, or flow coating.

The thickness of each layer is not particularly limited as long as each layer has an appropriate thickness. If the thickness of each layer is too large, a high applied voltage may be required to obtain constant optical output, so that the efficiency may deteriorate. If the thickness of each layer is too small, pinholes or the like may occur, so that sufficient luminance may not be obtained even if an electric field is applied. The thickness of each layer is normally 5 nm to 10 μm, and preferably 10 nm to 0.2 μm.

### EXAMPLES

The invention will be explained in more detail in accordance with the following synthesis examples and examples, which should not be construed as limiting the scope of the invention.

### Material for an Organic Electroluminescence Device

### Synthesis Example 1

### Synthesis of Compound (1)

### Synthesis of Compound (1-a)

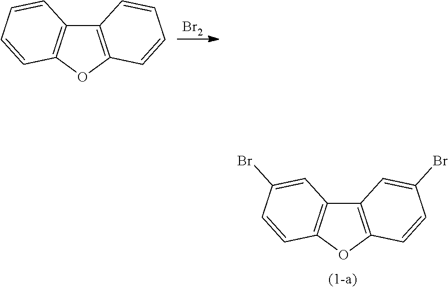

84.10 g (500 mmol) of dibenzofuran and 500 ml of dichloromethane were placed in a three-neck flask to allow the dibenzofuran to be dissolved in the dichloromethane. The resulting solution was cooled to 0° C. in ice water. Then, a solution of bromine 52.5 ml (1025 mmol)/dichloromethane 200 ml was added dropwise over 30 minutes. Then, the resulting mixture was stirred at 0° C. for 2 hours, and subsequently, was allowed to stand at room temperature. The reaction was completed after stirring for 3 days. After completion of the reaction, an aqueous solution of sodium thiosulfate/sodium hydroxide was added to allow the remaining bromine to be deactivated. The resultant was transferred to a separating funnel, a dichloromethane phase was recovered, and extraction was conducted several times from an aqueous phase with dichloromethane. The solution was dried with anhydrous magnesium sulfate, filtered, and concentrated and evaporated to dryness by passing through a silica gel short column. The resultant was re-crystallized twice from a mixed solvent of toluene and hexane, whereby white solids (compound (1-a)) were obtained. The yield was 105.9 g (65%).

### (2) Synthesis of Compound (1-b)

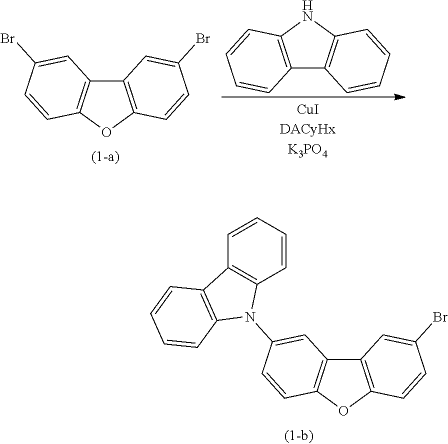

In a nitrogen atmosphere, 50.2 g (300 mmol) of carbazole, 97.8 g (300 mmol) of compound (1-a), 28.6 g (150 mmol) of copper iodide, 191.0 g (900 mmol) of potassium phosphate, 72.1 ml (600 mmol) of trans-1,2-diaminocyclohexane and 600 ml of 1,4-dioxane were placed in a three-neck flask. The resultant was refluxed for 24 hours. After the completion of the reaction, the resultant was cooled to room temperature, and then cooled with 1000 ml of toluene. Inorganic salts or the like were filtered by suction filtration, and the filtrate was passed through a short column of silica gel, and concentrated. The resultant was washed with a mixed solvent of ethyl acetate/methanol, whereby white solids (compound (1-b)) were obtained. The yield was 60.6 g (49%).

### (3) Synthesis of Compound (1-c)

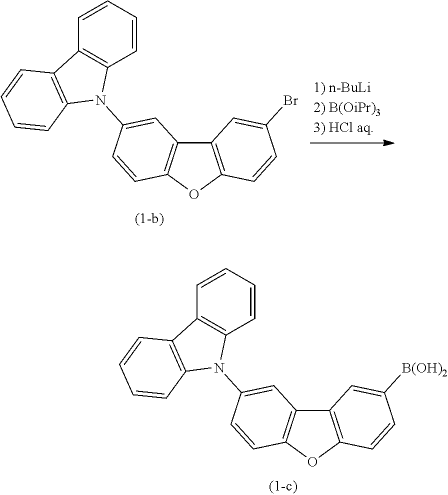 [SMILES: Brc1ccc2oc3ccc(-n4c5ccccc5c5ccccc54)cc3c2c1 ; OB(O)c1ccc2oc3ccc(-n4c5ccccc5c5ccccc54)cc3c2c1]

In a nitrogen atmosphere, 11.5 g (28 mmol) of compound (1-b) and 200 ml of dehydrated tetrahydrofuran were placed in a three-neck flask to allow the sample to be dissolved. The resultant was cooled to −78° C. To the mixed solution, 23.2 ml (1.57M in hexane, 36.4 mmol) of n-butyllithium was added dropwise for 10 minutes. After stirring at −78° C. for 20 minutes, 11.0 ml (47.6 mmol) of triisopropyl borate was added all at once, followed by stirring at room temperature for 3 hours.

After completion of the reaction, the solution was concentrated to about half. Then, 20 ml of an aqueous hydrogen chloride solution (1N) was added, and stirred at room temperature for 2 hours. Extraction was conducted with dichloromethane by means of a separating funnel, and then dried with anhydrous magnesium sulfate, filtrated and concentrated. The filtrate was passed through a short column of silica gel, and concentrated. To the resultant, hexane was added to conduct washing with dispersion, and filtrated to obtain white solids (compound (1-c)). The yield was 6.66 g (63%).

### (4) Synthesis of Compound (1)

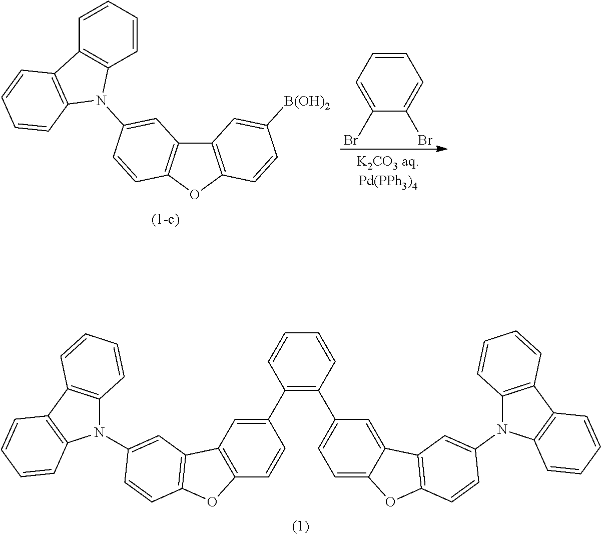 [SMILES: OB(O)c1ccc2oc3ccc(-n4c5ccccc5c5ccccc54)cc3c2c1 ; Brc1ccccc1Br ; c1ccc(-c2ccc3oc4ccc(-n5c6ccccc6c6ccccc65)cc4c3c2)c(-c2ccc3oc4ccc(-n5c6ccccc6c6ccccc65)cc4c3c2)c1]

In a nitrogen atmosphere, 5.66 g (15.0 mmol) of compound (1-c), 0.59 ml (5.0 mmol) of 1,2-dibromobenzene, 18.0 ml of potassium carbonate 2M aqueous solution and 100 ml of toluene were placed in a three-neck flask. To the mixed solution, 0.81 g (0.700 mmol) of tetrakis(triphenylphosphine)palladium was added, and refluxed for 14 hours.

After completion of the reaction, the resultant was cooled to room temperature, and extraction was conducted with dichloromethane by means of a separating funnel. The solution was dried with anhydrous magnesium sulfate, filtered, and concentrated. The filtrate was purified by passing through a short column of silica gel (eluent toluene:hexane=2:1) to obtain compound (1). The yield was 1.85 g (50%).

As a result of analysis of the steric structure of the compound (1) obtained in Synthesis Example 1, a configuration showing below was found to be the best steric structure. Additionally, it is found that C₁-L bond and C₂-L bond of the formula (1) could not rotate independently. That is, since the two Ls were arranged in parallel, the planarity of material molecules becomes high in all steric configurations that can be taken. As a result, since the orientation of material molecules in the device is improved, the carrier transporting properties and the carrier balance in the device can be improved. Additionally, reduction in the number of steric structures that can be taken by material molecules means reduction in vibration level that can be taken by material molecules, and capability of confining exciton within the emitting material in the device is improved. Meanwhile, the analysis was conducted by calculation using Gausian 98 in B3LYP/6-31g* level.

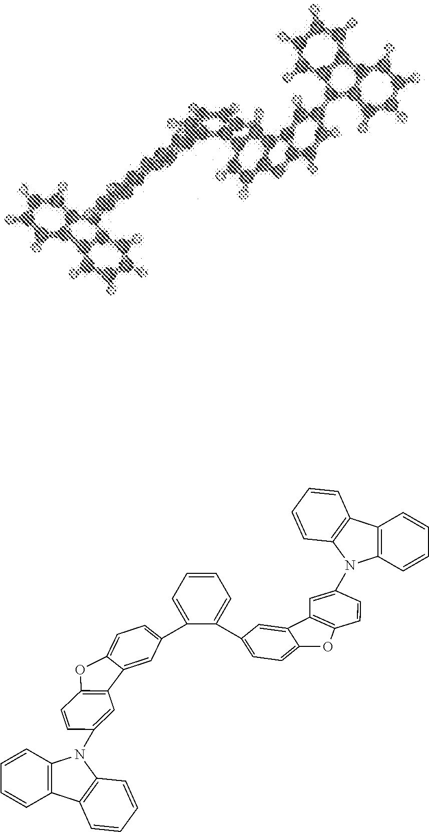 [SMILES: c1ccc(-c2ccc3oc4ccc(-n5c6ccccc6c6ccccc65)cc4c3c2)c(-c2ccc3oc4ccc(-n5c6ccccc6c6ccccc65)cc4c3c2)c1]

### Synthesis Example 2

### Synthesis of Compound (59)

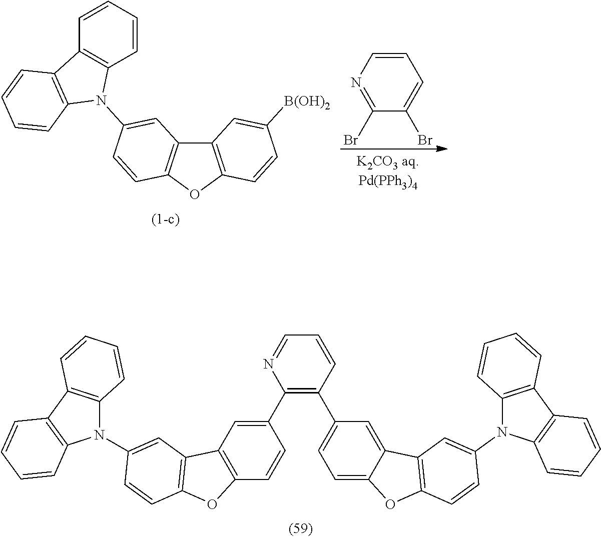 [SMILES: OB(O)c1ccc2oc3ccc(-n4c5ccccc5c5ccccc54)cc3c2c1 ; Brc1cccnc1Br ; c1cnc(-c2ccc3oc4ccc(-n5c6ccccc6c6ccccc65)cc4c3c2)c(-c2ccc3oc4ccc(-n5c6ccccc6c6ccccc65)cc4c3c2)c1]

In a nitrogen atmosphere, 15.3 g (40.6 mmol) of compound (1-c), 4.00 ml (16.9 mmol) of 2,3-dibromopyridine, 60 ml of potassium carbonate 2M aqueous solution, 160 ml of toluene and 60 ml of ethanol were placed in a three-neck flask. To the mixed solution, 0.976 g (0.845 mmol) of tetrakis(triphenylphosphine)palladium was added, and refluxed for 16 hours.

After completion of the reaction, the resultant was cooled to room temperature, and extraction was conducted with dichloromethane by means of a separating funnel. The solution was dried with anhydrous magnesium sulfate, filtered, and concentrated. The filtrate was purified by passing through a short column of silica gel (eluent dichloromethane-dichloromethane:ethyl acetate=4:1) to obtain compound (59). The yield was 4.50 g (36%).

### Synthesis Example 3

### Synthesis of Compound (60)

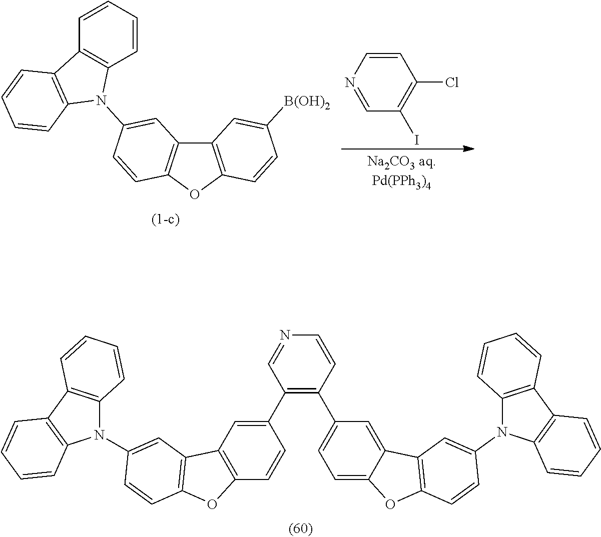 [SMILES: OB(O)c1ccc2oc3ccc(-n4c5ccccc5c5ccccc54)cc3c2c1 ; Clc1ccncc1I ; c1ccc2c(c1)c1ccccc1n2-c1ccc2oc3ccc(-c4ccncc4-c4ccc5oc6ccc(-n7c8ccccc8c8ccccc87)cc6c5c4)cc3c2c1]

In a nitrogen atmosphere, 7.56 g (20.0 mmol) of compound (1-c), 2.00 g (8.35 mmol) of 4-chloro-3-iodopyridine, 30 ml of potassium carbonate 2M aqueous solution, 80 ml of toluene and 30 ml of ethanol were placed in a three-neck flask. To the mixed solution, 0.482 g (0.418 mmol) of tetrakis(triphenylphosphine)palladium was added, and refluxed for 16 hours.

After completion of the reaction, the resultant was cooled to room temperature, and extraction was conducted with dichloromethane by means of a separating funnel. The solution was dried with anhydrous magnesium sulfate, filtered, and concentrated. The filtrate was purified by passing through a short column of silica gel (eluent dichloromethane-dichloromethane:ethyl acetate=4:1) to obtain compound (60). The yield was 3.38 g (55%).

### Synthesis Example 4

### Synthesis of Compound (2)

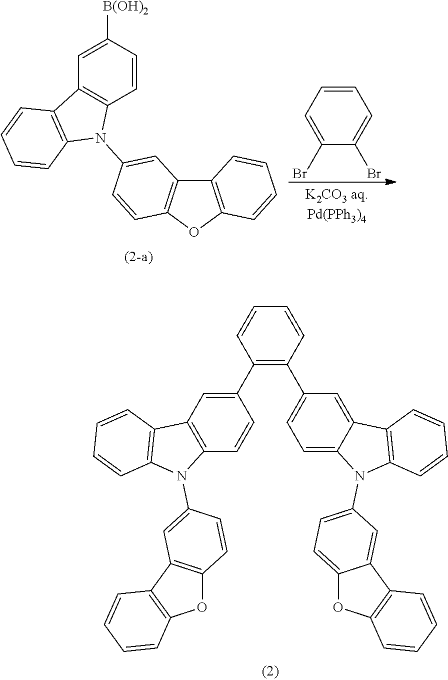

In a nitrogen atmosphere, 5.66 g (15.0 mmol) of compound (2-a), 0.59 ml (5.0 mmol) of 1,2-dibromobenzene, 18.0 ml of potassium carbonate 2M aqueous solution and 100 ml of toluene were placed in a three-neck flask. To the mixed solution, 0.81 g (0.700 mmol) of tetrakis(triphenylphosphine)palladium was added, and refluxed for 24 hours.

After completion of the reaction, the resultant was cooled to room temperature, and extraction was conducted from an aqueous phase with dichloromethane by means of a separating funnel. The solution was dried with anhydrous magnesium sulfate, filtered, and concentrated. The filtrate was purified by passing through a short column of silica gel (eluent toluene:hexane=3:1) to obtain compound (2). The yield was 1.33 g (36%).

Meanwhile, compound (2-a) can be synthesized in accordance with the method described in WO2011-122132.

### Organic EL Device

### Example 1

A glass substrate with an ITO electrode line having a film thickness of 130 nm (manufactured by GEOMATIC Co., Ltd.) was subjected to ultrasonic cleaning in isopropyl alcohol for 5 minutes and then UV ozone cleaning for 30 minutes.

The cleaned glass substrate with an ITO electrode line was mounted on a substrate holder in a vacuum deposition apparatus. First, compound (HI1) and then compound (HT1) were deposited subsequently by resistance heating deposition on the surface on which the ITO electrode lines had been formed so as to cover the ITO electrode line to form a 20 nm thick film and a 60 nm thick film, respectively. The film forming rate was 1 Å/s. These films serve as a hole-injecting layer and an electron-transporting layer, respectively.

Next, the compound (1) and the compound (BD1) were deposited on the hole-injecting/transporting layer by resistance heating deposition at the same time to form a thin film of 50 nm thick. The deposition amount of the compound (BD1) was 20% in mass ratio to the total amount of compound (1) and compound (BD1). The film forming rates were 1.2 Å/s and 0.3 Å/s, respectively. The thin film serves as a phosphorescent emitting layer.

Next, compound (H1) was deposited on the phosphorescent emitting layer by resistance heating deposition to form a thin film of 10 nm thick. The forming film rate was 1.2 Å/s. The thin film serves as a barrier layer.

Next, compound (ET1) was deposited on the barrier layer by resistance heating deposition to form a thin film of 10 nm thick. The film forming rate was 1 Å/s. The thin film serves as an electron-injecting layer.

Next, LiF was deposited on the electron injecting layer at the film forming rate of 0.1 Å/s to form a 1.0 nm-thick film.

Next, on the LiF film, metal aluminum was deposited at the film forming rate of 8.0 Å/s to form a metal cathode having a 80 nm film thickness, whereby an organic EL device was obtained.

The organic EL device obtained as mentioned above was evaluated by the following method. The results are shown in Table 1

### (1) External Quantum Efficiency (%)

In a dry nitrogen gas atmosphere of 23° C., the external quantum efficiency at a luminance of 1000 cd/m² was measured by using a luminance meter (spectroradiometer CS 1000 manufactured by Konica Minolta, Inc.).

### (2) Half Life (Hour(s))

A time that elapses until the initial luminance was reduced by half was measured by conducting a continuous current test (direct current) at an initial luminance of 1000 cd/m².

### (3) Voltage (V)

In a dry nitrogen gas atmosphere of 23° C., a voltage was applied to a device in which electric wiring had been conducted by means of KEITHLY 236 SOURCE MEASURE UNIT, thereby to cause the device to emit light. Then, a voltage concerning on the wiring resistance other than that for the device was deducted, whereby a voltage applied to the device was measured. The luminance was measured at the same time of applying and measuring the voltage, by using spectroradiometer CS 1000 manufactured by Konica Minolta, Inc.). The voltage at a device luminance of 100 cd/m² was determined from these measurement results.

### Example 2

An organic EL device was fabricated and evaluated in the same manner as in Example 1, except that compound (59) was used instead of compound (1) as the phosphorescent emitting layer material. The results are shown in Table 1.

### Example 3

An organic EL device was fabricated and evaluated in the same manner as in Example 1, except that compound (60) was used instead of compound (1) as the phosphorescent emitting layer material. The results are shown in Table 1.

### Example 4

An organic EL device was fabricated and evaluated in the same manner as in Example 1, except that compound (2) was used instead of compound (1) as the phosphorescent emitting layer material. The results are shown in Table 1.

The results are shown in Table 1.

TABLE 1

| | Emitting | Voltage | External quantum | Half life of |
|---|---|---|---|---|
| | layer | (V) | efficiency (%) | luminance (hrs) |
| Example 1 | Compound (1) | 4.9 | 15.5 | 5400 |
| Example 2 | Compound (59) | 4.5 | 14.5 | 3500 |
| Example 3 | Compound (60) | 4.0 | 14.2 | 3000 |
| Example 4 | Compound (2) | 4.7 | 15.3 | 4300 |

### Example 5

An organic EL device was fabricated and evaluated in the same manner as in Example 1, except that compound (H1) was used instead of compound (1) as the phosphorescent emitting layer material, and compound (1) was used instead of compound (H1) as the hole barrier layer to form the hole barrier layer. The results are shown in Table 2.

### Example 6

An organic EL device was fabricated and evaluated in the same manner as in Example 1, except that compound (H1) was used instead of compound (1) as the phosphorescent emitting layer material, and compound (59) was used instead of compound (H1) as the hole barrier layer material to form the hole barrier layer. The results are shown in Table 2.

### Example 7

An organic EL device was fabricated and evaluated in the same manner as in Example 1, except that compound (H1) was used instead of compound (1) as the phosphorescent emitting layer material, and compound (60) was used instead of compound (H1) as the hole barrier layer material to form the hole barrier layer. The results are shown in Table 2.

### Example 8

An organic EL device was fabricated and evaluated in the same manner as in Example 1, except that compound (H1) was used instead of compound (1) as the phosphorescent emitting layer material, and compound (2) was used instead of compound (H1) as the hole barrier layer material to form the hole barrier layer. The results are shown in Table 2.

TABLE 2

| | Hole blocking | Voltage | External quantum | Half life of |
|---|---|---|---|---|
| | layer | (V) | efficiency (%) | luminance (hrs) |
| Example 5 | Compound (1) | 6.0 | 17.9 | 9000 |
| Example 6 | Compound (59) | 5.3 | 17.9 | 6500 |
| Example 7 | Compound (60) | 5.0 | 17.9 | 5800 |
| Example 8 | Compound (2) | 5.7 | 16.8 | 7300 |

The structural formulas of the compounds used in Examples are shown below.

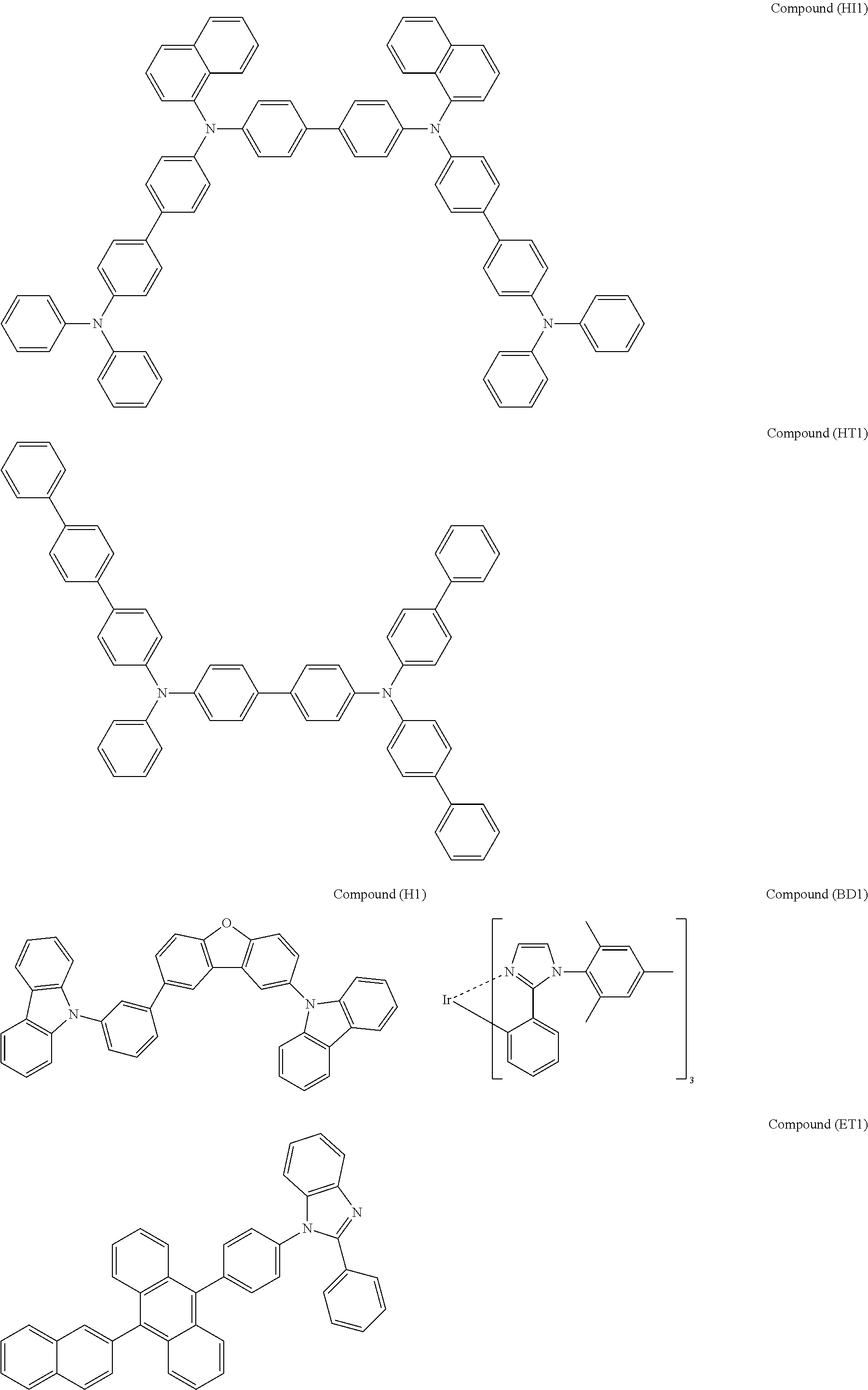

Triplet energies of the material for an organic EL device used in Examples are shown in Table 3. The triplet energy is measured using the sample for phosphorescence measurement. The sample is prepared by dissolving the material in EPA solvent (diethyl ether:isopentane:ethanol=5:5:2 (volume ratio)) at a concentration of 10 μmol/L. The sample for phosphorescence measurement is placed in a quartz cell. The sample in the quartz cell was irradiated with excited light at 77 K, and the phosphorescence spectrum of the emitted phosphorescent light was measured. The triplet energy was defined as the value obtained by calculating on the measurement value using the conversion equation of E^{T} (eV)=1239.85/λ_{edge}.

TABLE 3

| Compound | Triplet energy (eV) |
|---|---|
| Compound (1) | 3.03 |
| Compound (59) | 3.02 |
| Compound (60) | 3.03 |
| Compound (2) | 2.97 |
| Compound (BD1) | 2.64 |

Tables 1 and 2 show that the organic EL device obtained by using the material for an organic EL device of the invention can have a long life, exhibit a high luminous efficiency and can be driven at a low voltage.

Moreover, Table 3 shows that the material for an organic EL device of the invention is a material having a high triplet energy which can be used as a host material for blue phosphorescence emission.

### INDUSTRIAL APPLICABILITY

The organic EL device of the invention can be used in a planar luminous body such as a flat panel display of a wall-hanging TV, a copier, a printer, a backlight of a crystal liquid display, or a light source of instruments, a displaying board, sign lighting or the like.

The material for an organic EL device of the invention can be used for an organic EL device, an organic EL display, lighting, an organic semiconductor and an organic solar cell, etc.

The material for an organic EL device of the invention is useful as a material for an organic EL device that can allow an organic EL device to be driven at a low voltage and as an organic EL device having a high luminous efficiency and a long life as well as a material for an organic EL device that realizes such an organic EL device.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification of a Japanese application on the basis of which the present application claims Paris convention priority are incorporated herein by reference in its entirety.

1. A compound represented by the following formula (1): 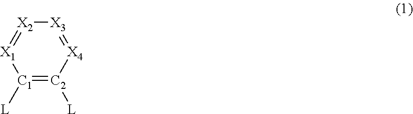
wherein in the formula (1), C₁ and C₂ are independently a carbon atom;
X₁ to X₄ are independently N, CH or C(R₁);
R₁ are independently a single bond, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 6 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphonyl group, a fluoro group or a cyano group; provided that if two adjacent groups of X₁ to X₄ are both C(R₁) and one of R₁s a single bond, the single bond is used in the bond to the other R₁ to form a ring comprising the two carbon atoms;
L is independently a group represented by the following formula (2):
-L₁-(A)ₙ (2)
wherein in the formula (2), n is the number of A being bonded sequentially, and is an integer of 0 to 6; when n is 2 or more, plural As may be the same or different;
A is a group selected from a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 6 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a divalent group corresponding thereto, a fluoro group and a cyano group;
L₁ is a group represented by the following formula (3): 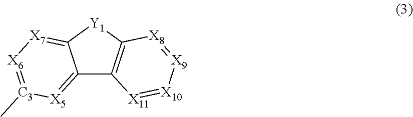
wherein in the formula (3), C₃ is a carbon atom, and C₃ is bonded to C₁ or C₂ in the formula (1);
Y₁ is O, S, NH, N(R₂) or a nitrogen atom that is bonded to A;
X₅ to X₁₁ are independently N, CH, C(R₃) or a carbon atom that is bonded to A;
R₂ and R₃ are independently a single bond, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 6 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group, provided that if two adjacent groups of X₆ to X₁₁ are both C(R₃) and one of R₃s is a single bond, the single bond is used in the bond to the other R₃ to form a ring comprising the two carbon atoms.

2. The compound according to claim 1, wherein A in at least one of the two Ls comprises a substituted or unsubstituted heteroaryl group including 13 to 18 ring atoms or a substituted or unsubstituted heteroarylene group including 13 to 18 ring atoms.

3. The compound according to claim 1, wherein A in at least one of the two Ls comprises a heteroaryl group or a heteroarylene group represented by the following formula (4): 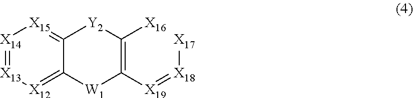
wherein in the formula (4), X₁₂ to X₁₉ are independently N, CH, C(R₄) or a carbon atom that is bonded to L₁ or A;
R₄ is independently a single bond, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group, provided that if two adjacent groups of X₁₂ to X₁₉ are both C(R₄) and one of R₄s is a single bond, the single bond is used in the bond to the other R₄ to form a ring comprising the two carbon atoms;
Y₂ is O, S, NH, N(R₅) or a nitrogen atom that is bonded to L₁ or A;
R₅ is a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group;
W₁ is a single bond, O, S, S(═O)₂, P(R₆), P(═O)(R₇), N(R₈), Si(R₉)(R₁₀), C(R₁₁)(R₁₂), a nitrogen atom that is bonded to L₁ or A or a carbon atom that is bonded to L₁ or A; and
R₆ to R₁₂ are independently a hydrogen atom, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group.

4. The compound according to claim 1, wherein A in at least one of the two Ls comprises a heteroaryl group or a heteroarylene group represented by the following formula (5): 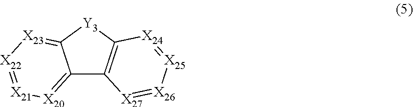
wherein in the formula (5), X₂₀ to X₂₇ are independently N, CH, C(R₁₃) or a carbon atom that is bonded to L₁ or A;
R₁₃ is independently a single bond, a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring carbon atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group, provided that if two adjacent groups of X₂₀ to X₂₇ are both C(R₁₃) and one of R₁₃s is a single bond, the single bond is used in the bond to the other R₁₃ to form a ring comprising the two carbon atoms;
Y₃ is O, S, NH, N(R₁₄) or a nitrogen atom that is bonded to L₁ or A;
R₁₄ is a substituted or unsubstituted alkyl group including 1 to 20 carbon atoms, a substituted or unsubstituted cycloalkyl group including 3 to 18 ring carbon atoms, a substituted or unsubstituted alkoxy group including 1 to 20 carbon atoms, a substituted or unsubstituted cycloalkoxy group including 3 to 18 ring carbon atoms, a substituted or unsubstituted aryl group including 6 to 18 ring carbon atoms, a substituted or unsubstituted aryloxy group including 6 to 18 ring carbon atoms, a substituted or unsubstituted arylthio group including 5 to 18 ring atoms, a substituted or unsubstituted heteroaryl group including 5 to 18 ring atoms, a substituted or unsubstituted heteroaryloxy group including 5 to 18 ring atoms, a substituted or unsubstituted amino group, a substituted or unsubstituted silyl group, a substituted or unsubstituted diaryloxyphosphinyl group, a fluoro group or a cyano group:

5. The compound according to claim 1, wherein n in one of the two Ls is 0.

6. A material for an organic electroluminescence device comprising the compound according to claim 1.

7. An organic electroluminescence device comprising:
a cathode and an anode;
one or more organic thin film layers including an emitting layer between the cathode and the anode; and
at least one layer of the organic thin film layers comprising the material for an organic electroluminescence device according to claim 6.

8. The organic electroluminescence device according to claim 7, wherein the emitting layer comprises the material for an organic electroluminescence device as a host material.

9. The organic electroluminescence device according to claim 7, wherein the emitting layer comprises a phosphorescent emitting material which is an ortho-metalated complex of a metal atom selected from iridium (Ir), osmium (Os) and platinum (Pt).

10. The organic electroluminescence device according to claim 7, wherein the layer that comprises the material for an organic electroluminescence device forms an electron-transporting region between the cathode and the emitting layer.

11. The organic electroluminescence device according to claim 7, wherein the layer that comprises the material for an organic electroluminescence device is an electron-injecting layer between the emitting layer and the cathode.

12. The organic electroluminescence device according to claim 7, wherein the layer that comprises the material for an organic electroluminescence device is a hole-transporting region between the emitting layer and the anode.
